(19) United States
(12) Patent Application Publication
(10) Pub. No.: US 2024/0121998 A1
(43) Pub. Date: Apr. 11, 2024

(54) THIN-FILM TRANSISTOR, TRANSISTOR ARRAY SUBSTRATE, AND METHOD OF FABRICATING THE TRANSISTOR ARRAY SUBSTRATE

(71) Applicant: Samsung Display Co., LTD., Yongin-si (KR)

(72) Inventors: Sun Hee LEE, Yongin-si (KR); Eun Hye KO, Yongin-si (KR); Sang Woo SOHN, Yongin-si (KR); Jung Hoon LEE, Yongin-si (KR); Hyun Mo LEE, Yongin-si (KR); Hyun Jun JEONG, Yongin-si (KR)

(21) Appl. No.: 18/446,234

(22) Filed: Aug. 8, 2023

(30) Foreign Application Priority Data
Oct. 6, 2022 (KR) 10-2022-0128195
Feb. 27, 2023 (KR) 10-2023-0026098

(51) Int. Cl. H10K 59/124; H10K 59/12; H10K 59/131

(52) U.S. Cl. CPC H10K 59/124; H10K 59/1201; H10K 59/131

(57) ABSTRACT

A thin-film transistor including an active layer disposed on a substrate and including a channel region, a source region connected to a side of the channel region, and a drain region connected to the other side of the channel region; a gate insulating layer on the channel region of the active layer; and a gate electrode on the gate insulating layer. A slope of each side surface of the gate electrode with respect to a boundary surface between the gate insulating layer and the gate electrode is an obtuse angle (a substantially obtuse angel). A slope of each side surface of the gate insulating layer with respect to the boundary surface between the gate insulating layer and the gate electrode is an obtuse angle (a substantially obtuse angel).

### CROSS-REFERENCE TO RELATED APPLICATION

This application claims priority to and the benefit of Korean Patent Application No. 10-2022-0128195, filed on Oct. 6, 2022, in the Korean Intellectual Property Office, and the benefit of Korean Patent Application No. 10-2023-0026098, filed on Feb. 27, 2023, in the Korean Intellectual Property Office, the entire content of both of which is incorporated herein in its entirety by reference.

### BACKGROUND

### 1. Field

One or more embodiments of the present disclosure related to a thin-film transistor, a transistor array substrate, and a method of fabricating the transistor array substrate.

### 2. Description of the Related Art

As the information society develops, demands for display devices for displaying images are increasing in one or more suitable forms. For example, display devices may be incorporated in one or more suitable electronic devices such as smartphones, digital cameras, notebook computers, navigation devices, and/or smart televisions.

The above information disclosed in this Background section is for enhancement of understanding of the background of the present disclosure, and therefore, it may contain information that does not constitute prior art.

### SUMMARY

A display device may include a display panel that emits light for displaying an image and a driver that supplies signals or power for driving the display panel.

The display panel may include a display area from which light for displaying an image is emitted and may include a polarizing member or a light emitting member in the display area.

Pixels displaying their respective luminance and colors may be arranged in the display area. Each of the pixels may include three or more subpixels that are adjacent to each other and emit light of three or more different colors.

The display panel may include a transistor array substrate including a substrate and a circuit layer which is disposed on the substrate and includes pixel drivers respectively corresponding to the subpixels. Light emitting elements respectively corresponding to the subpixels of the display area may be individually driven by the pixel drivers of the circuit layer.

Each of the pixel drivers of the circuit layer of the transistor array substrate may include at least one thin-film transistor.

A thin-film transistor includes a gate electrode and an active layer. The active layer includes a channel region and also include a source region and a drain region connected to both (opposite or left and right) ends (sides) of the channel region. Accordingly, the thin-film transistor may be a switching element in which the source region and the drain region are electrically connected through the channel region of the active layer when a voltage difference between any one selected from the source and drain regions and the gate electrode is equal to or greater than a threshold according to a driving signal transmitted to the gate electrode.

The thin-film transistor may be classified as a top-gate structure or a bottom-gate structure according to a positional relationship between the active layer and the gate electrode. In some embodiments, the thin-film transistor may be a double-gate structure including two gate electrodes disposed above and below the active layer.

A top-gate structure thin-film transistor may include a gate insulating layer disposed on a channel region of an active layer and a gate electrode disposed on the gate insulating layer. In some embodiments, the active layer and the gate electrode of the thin-film transistor may be covered with an interlayer insulating layer.

For high resolution of a display device, the gate electrode may include a metal material having a relatively low resistivity. In some embodiments, for high resolution of the display device, when the gate insulating layer and the gate electrode are placed, the metal material may be etched by isotropic dry etching having a relatively small process error compared with anisotropic wet etching. However, when a pattern is provided by dry etching, side surfaces of the pattern may have a steep slope close to (about or substantially) vertical. Therefore, cracks or gaps may be easily generated in an insulating layer covering the pattern.

For example, due to step coverage, a thickness of the interlayer insulating layer covering side surfaces of the gate insulating layer may be smaller (less) than a thickness of the interlayer insulating layer covering an upper surface of the gate electrode.

In addition, when the side surfaces of the gate insulating layer have a steep slope close to vertical, cracks or gaps may be generated in the interlayer insulating layer by the slope of the side surfaces of the gate insulating layer with respect to the active layer. Accordingly, the active layer may not be completely covered with the interlayer insulating layer. This may cause breaking of the active layer or deterioration of semiconductor characteristics of the active layer, thereby rapidly reducing the lifespan of the thin-film transistor and deteriorating the uniformity of characteristics of the thin-film transistor.

Aspects of embodiments of the present disclosure may be directed toward a thin-film transistor advantageous for high resolution and capable of preventing or reducing breaking of an active layer and deterioration of semiconductor characteristics of the active layer, a transistor array substrate including the thin-film transistor, and a method of fabricating the transistor array substrate.

However, aspects of the present disclosure are not restricted to the one set forth herein. The above and additional aspects of the present disclosure will be set forth in part in the description, which follow and, in part, will become more apparent to one of ordinary skill in the art to which the present disclosure pertains by referencing the detailed description of the present disclosure described herein.

According to one or more embodiments of the present disclosure, a thin-film transistor includes an active layer on a substrate and including a channel region, a source region connected to a side of the channel region, and a drain region connected to a different side of the channel region; a gate insulating layer on the channel region of the active layer; and a gate electrode on the gate insulating layer. A slope of each side surface of the gate electrode with respect to a boundary surface between the gate insulating layer and the gate electrode is an obtuse angle (a substantially obtuse angel). A slope of each side surface of the gate insulating layer with respect to the boundary surface between the gate insulating layer and the gate electrode is an obtuse angle (a substantially obtuse angel).

In an embodiment, the active layer and the gate electrode are covered with an interlayer insulating layer arranged substantially flat on the substrate. The gate electrode includes an electrode main layer; and an electrode barrier layer between the electrode main layer and the gate insulating layer and between side surfaces of the electrode main layer and the interlayer insulating layer.

In an embodiment, the electrode main layer includes a single layer or a multilayer including at least one metal material selected from molybdenum (Mo), aluminum (Al), chromium (Cr), gold (Au), titanium (Ti), nickel (Ni), neodymium (Nd), copper (Cu), and alloys of two or more thereof. The electrode barrier layer includes a metal oxide material including one or more metal materials selected from indium (In), gallium (Ga), zinc (Zn), tin (Sn), aluminum (Al) and molybdenum (Mo).

In an embodiment, the active layer includes an oxide semiconductor material including one or more metal materials selected from indium (In), gallium (Ga), zinc (Zn), tin (Sn), aluminum (Al) and molybdenum (Mo). Each of the source region and the drain region in the active layer includes conductivity (is a conductor).

In an embodiment, the interlayer insulating layer includes a first interlayer insulating layer contacting the source region of the active layer and the drain region of the active layer, the gate insulating layer, and the gate electrode; and a second interlayer insulating layer arranged substantially flat on the first interlayer insulating layer.

In an embodiment, the thin-film transistor further includes a light blocking layer on a first buffer layer covering the substrate and overlapping at least the channel region of the active layer. The active layer is on a second buffer layer covering the light blocking layer.

In an embodiment, the second buffer layer is disposed arranged substantially flat.

In an embodiment, side surfaces of the light blocking layer contact the first buffer layer.

In an embodiment, the light blocking layer includes a single layer or a multilayer including at least one metal material selected from molybdenum (Mo), aluminum (Al), chromium (Cr), gold (Au), titanium (Ti), nickel (Ni), neodymium (Nd), copper (Cu), and alloys of two or more thereof.

According to one or more embodiments of the present disclosure, a transistor array substrate includes a substrate including a display area comprising subpixels; and a circuit layer on the substrate and including pixel drivers respectively corresponding to the subpixels. Each of the pixel drivers includes at least one thin-film transistor. The one thin-film transistor of the circuit layer includes an active layer on the substrate and including a channel region, a source region connected to a side of the channel region, and a drain region connected to a different side of the channel region; a gate insulating layer on the channel region of the active layer; and a gate electrode on the gate insulating layer. A slope of each side surface of the gate electrode with respect to a boundary surface between the gate insulating layer and the gate electrode is an obtuse angle (a substantially obtuse angel). A slope of each side surface of the gate insulating layer with respect to the boundary surface between the gate insulating layer and the gate electrode is an obtuse angle (a substantially obtuse angel).

In an embodiment, the circuit layer further includes an interlayer insulating layer covering the active layer and the gate electrode and arranged substantially flat on the substrate. The gate electrode includes an electrode main layer; and an electrode barrier layer between the electrode main layer and the gate insulating layer and between a side surface of the electrode main layer and a side surface of the interlayer insulating layer.

In an embodiment, the electrode main layer includes a single layer or a multilayer including at least one metal material selected from molybdenum (Mo), aluminum (Al), chromium (Cr), gold (Au), titanium (Ti), nickel (Ni), neodymium (Nd), copper (Cu), and alloys of two or more thereof. The electrode barrier layer includes a metal oxide material including one or more metal materials selected from indium (In), gallium (Ga), zinc (Zn), tin (Sn), aluminum (Al) and molybdenum (Mo).

In an embodiment, the interlayer insulating layer includes a first interlayer insulating layer contacting the source region of the active layer and the drain region of the active layer, the gate insulating layer, and the gate electrode; and a second interlayer insulating layer arranged substantially flat on the first interlayer insulating layer.

In an embodiment, one thin-film transistor of the circuit layer further includes a light blocking layer on a first buffer layer covering the substrate and overlapping at least the channel region of the active layer. The active layer is on a second buffer layer covering the light blocking layer.

In an embodiment, the second buffer layer is arranged substantially flat.

In an embodiment, side surfaces of the light blocking layer contact the first buffer layer.

In an embodiment, the transistor array substrate further includes a light emitting element layer on the circuit layer and including light emitting elements electrically connected to the pixel drivers. One of the pixel drivers is configured to transmit a driving current to one of the light emitting elements and includes a first thin-film transistor connected in series to the light emitting element between a first power line and a second power line configured to transmit first power and second power for driving the light emitting elements; a second thin-film transistor electrically connected between a data line configured to transmit a data signal and a gate electrode of the first thin-film transistor and configured to be turned on based on a scan signal of a scan gate line; and a pixel capacitor electrically connected to a first node between the gate electrode of the first thin-film transistor and the second thin-film transistor and a second node between the first thin-film transistor and the light emitting element,

In an embodiment, a first electrode of the first thin-film transistor is electrically connected to the first power line. A second electrode of the first thin-film transistor is electrically connected to an anode of the light emitting element.

In an embodiment, the circuit layer further includes a wiring conductive layer on the interlayer insulating layer; and a via layer arranged substantially flat on the interlayer insulating layer and covering the wiring conductive layer. The wiring conductive layer includes the data line; the first power line; a gate connection electrode electrically connecting a gate electrode of the second thin-film transistor and a light blocking layer of the second thin-film transistor; and an anode connection electrode electrically connected to a source region of an active layer of the first thin-film transistor and a light blocking layer of the first thin-film transistor. The anode is on the via layer and electrically connected to the anode connection electrode.

In an embodiment, the circuit layer further includes a first capacitor electrode on the first buffer layer; a second capacitor electrode on the second buffer layer and overlapping the first capacitor electrode; and a third capacitor electrode on the interlayer insulating layer and overlapping the second capacitor electrode. The pixel capacitor is in an overlap area between each of the first capacitor electrode and the third capacitor electrode, the first capacitor electrode and the second capacitor electrode, and the second capacitor electrode and the third capacitor electrode.

According to one or more embodiments of the present disclosure, a method of fabricating a transistor array substrate includes placing a circuit layer on a substrate, the circuit layer including pixel drivers respectively corresponding to subpixels, each of the pixel drivers including at least one thin-film transistor, the substrate including a display area in which the subpixels are arranged; and placing a light emitting element layer including light emitting elements respectively corresponding to the subpixels and electrically connected to the pixel drivers, respectively, on the circuit layer. The placing of the circuit layer includes placing a thin-film transistor on the substrate; and placing an interlayer insulating layer covering the thin-film transistor, on the substrate. The placing of the thin-film transistor includes placing a first buffer layer on the substrate; placing a light blocking layer on the first buffer layer; placing a second buffer layer covering the light blocking layer, on the first buffer layer; placing a semiconductor material layer on the second buffer layer; and placing a gate insulating layer and a gate electrode on a portion of the semiconductor material layer. A slope of each side surface of the gate electrode with respect to a boundary surface between the gate insulating layer and the gate electrode is an obtuse angle (a substantially obtuse angel). A slope of each side surface of the gate insulating layer with respect to the boundary surface between the gate insulating layer and the gate electrode is an obtuse angle (a substantially obtuse angel).

In the placing of the gate insulating layer and the gate electrode, the gate electrode includes an electrode main layer; and an electrode barrier layer between the electrode main layer and the gate insulating layer and between a side surface of the electrode main layer and a side surface of the interlayer insulating layer.

In an embodiment, the placing of the gate insulating layer and the gate electrode includes placing an insulating material layer having a first thickness and covering the semiconductor material layer, on the second buffer layer; partially etching the insulating material layer to change a portion of the insulating material layer overlapping a portion of the semiconductor material layer, to a second thickness smaller than the first thickness; placing a metal oxide material layer on the insulating material layer; placing a metal material layer on the metal oxide material layer; providing the gate electrode including an electrode barrier layer and an electrode main layer. The electrode barrier layer includes the metal oxide material layer remaining on the insulating material layer having the second thickness, and the electrode main layer includes the metal material layer remaining on the electrode barrier layer, by performing ashing on the metal material layer and the metal oxide material layer until the insulating material layer having the first thickness is exposed; and removing the insulating material layer having the first thickness and providing the gate insulating layer including the insulating material layer having the second thickness and remaining between the gate electrode and the semiconductor material layer, by etching the Insulating material layer.

In an embodiment, the electrode barrier layer is placed between the electrode main layer and the gate insulating layer and surrounds (is around) the side surfaces of the electrode main layer. In the providing of the gate insulating layer, an active layer is provided. The active layer includes a channel region including a portion of the semiconductor material layer overlapping the gate electrode and a source region and a drain region respectively including one or more portions of the semiconductor material layer at both (opposite or left and right) ends (sides) of the channel region.

In an embodiment, the metal oxide material layer includes a metal oxide material including one or more metal materials selected from indium (In), gallium (Ga), zinc (Zn), tin (Sn), aluminum (Al) and molybdenum (Mo). The metal material layer includes a single layer or a multilayer including at least one metal material selected from molybdenum (Mo), aluminum (Al), chromium (Cr), gold (Au), titanium (Ti), nickel (Ni), neodymium (Nd), copper (Cu), and alloys of two or more thereof.

In an embodiment, placing of the interlayer insulating layer includes placing a first interlayer insulating layer contacting the source region of the active layer and the drain region of the active layer, the gate insulating layer, and the gate electrode; stacking an insulating material on the first interlayer insulating layer; and providing a flat second interlayer insulating layer by performing ashing on the insulating material stacked on the first interlayer insulating layer.

In an embodiment, placing of the second buffer layer includes providing a second buffer layer arranged substantially flat on the first buffer layer, by performing ashing on an insulating material stacked on the first buffer layer.

In an embodiment, the first buffer layer has a third thickness. The placing of the light blocking layer includes partially etching the first buffer layer to change a portion of the first buffer layer to a fourth thickness smaller than the third thickness; placing a light blocking material layer on the first buffer layer; and performing ashing on the light blocking material layer until the first buffer layer having the third thickness is exposed and providing the light blocking layer including the light blocking material layer remaining on the first buffer layer having the fourth thickness.

In an embodiment, side surfaces of the light blocking layer contact the first buffer layer.

According to an embodiment, the providing of the gate electrode in the placing of the gate insulating layer and the gate electrode includes a process (task or act) of performing ashing until the metal oxide material layer and the metal material layer on the insulating material layer having the second thickness remain. In other words, the providing of the gate electrode does not include a process of etching a metal material. Accordingly, side surfaces of the gate electrode can be prevented or reduced from having a steep slope close to vertical due to dry etching of the metal material layer.

In some embodiments, a slope of each side surface of the gate electrode corresponds to a slope of each side surface of a portion of the second buffer layer changed to the second thickness. Accordingly, because the slope of a portion of the second buffer layer can be adjusted in the changing of the portion of the second buffer layer to the second thickness, the slope of each side surface of the gate electrode can be adjusted relatively easily.

Thus, in the etching of the insulating material layer during the providing of the gate insulating layer, side surfaces of the gate insulating layer may have a relatively gentle slope due to the relatively gentle slope of the side surfaces of the gate electrode. For example, even when dry etching is performed on the insulating material layer, the side surfaces of the gate insulating layer can be prevented or reduced from having a steep slope close to vertical.

Therefore, generation of gaps or cracks in an interlayer insulating layer due to the steep slope of the gate insulating layer can be prevented or reduced. Accordingly, because the active layer can be completely covered with the interlayer insulating layer, it is possible to prevent or reduce breaking of the active layer and deterioration of semiconductor characteristics of the active layer, thereby preventing or reducing a reduction in the lifespan and uniformity of characteristics of the thin-film transistor.

A transistor array substrate including the above thin-film transistor can be easily applied to a high-resolution display device and can have a beneficial effect on improving the image quality of the display device.

However, the effects of the present disclosure are not limited to the aforementioned effects, and one or more suitable other effects are included in the present specification.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a plan view of the display device of FIG. 1;

FIG. 3 is a cross-sectional view of an example of a surface taken along line A-A′ of FIG. 1;

FIG. 4 is a layout view of an example of a circuit layer of FIG. 3;

FIG. 5 is an equivalent circuit diagram of an example of a subpixel of FIG. 4;

FIG. 6 is a cross-sectional view illustrating a first embodiment of a first thin-film transistor, a second thin-film transistor, and a pixel capacitor in a pixel driver of FIG. 5;

FIG. 7 is an enlarged view illustrating a first thin-film transistor of FIG. 6 in more detail;

FIG. 8 is a cross-sectional view illustrating a second embodiment of the first thin-film transistor, the second thin-film transistor, and the pixel capacitor in the pixel driver of FIG. 5;

FIG. 9 is a cross-sectional view illustrating a third embodiment of the first thin-film transistor, the second thin-film transistor, and the pixel capacitor in the pixel driver of FIG. 5;

FIG. 10 is a cross-sectional view illustrating a fourth embodiment of the first thin-film transistor, the second thin-film transistor, and the pixel capacitor in the pixel driver of FIG. 5;

FIG. 11 is a flowchart illustrating a method of fabricating a transistor array substrate according to an embodiment;

FIG. 12 is a flowchart illustrating detailed operations in an operation of placing a gate insulating layer and a gate electrode in FIG. 11; and

FIGS. 13-34 are process diagrams illustrating some operations of FIGS. 11 and 12.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying drawings, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” refers to when an object portion is viewed from above, and the phrase “in a schematic cross-sectional view” refers to when a schematic cross-section taken by vertically cutting an object portion is viewed from the side. The terms “overlap” or “overlapped” refer to that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may refer to that a first object may directly or indirectly oppose a second object. In a case in which a third object intervenes between a first and second object, the first and second objects may be understood as being indirectly opposed to one another, although still facing each other.

The spatially relative terms “,” “beneath,” “lower,” “above,” “upper,” and/or the like, may be utilized herein for ease of description to describe the relations between one element or component and another element or component as illustrated in the drawings. It will be understood that the spatially relative terms are intended to encompass different orientations of the device in utilize or operation, in addition to the orientation depicted in the drawings. For example, in the case where a device illustrated in the drawing is turned over, the device positioned “ ” ” or “beneath” another device may be placed “above” another device. Accordingly, the illustrative term “below” may include both (e.g., simultaneously) the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are utilized, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” and/or the like may be utilized herein to describe one or more suitable elements, these elements should not be limited by these terms. These terms are utilized to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “substantially”, “about”, “ “approximately” or similar terms utilized herein is inclusive of the stated value and refers to within an acceptable range of deviation for the particular value as determined by one of ordinary skill in the art, considering the measurement in question and the error associated with measurement of the particular quantity (for example, the limitations of the measurement system). For example, “about” may refer to within one or more standard deviations, or within ±30%, 20%, 10%, 5% of the stated value.

As utilized herein, the term “and/or” includes any and all combinations of one or more of the associated listed items. Throughout the disclosure, the expression “at least one of a, b or c”, “at least one of a-c”, “at least one of a to c”, “at least one of a, b, and/or c”, etc., indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

Unless otherwise defined or implied, all terms utilized herein (including technical and scientific terms) have the same meaning as commonly understood by those skilled in the art to which this disclosure pertains. It will be further understood that terms, such as those defined in commonly utilized dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

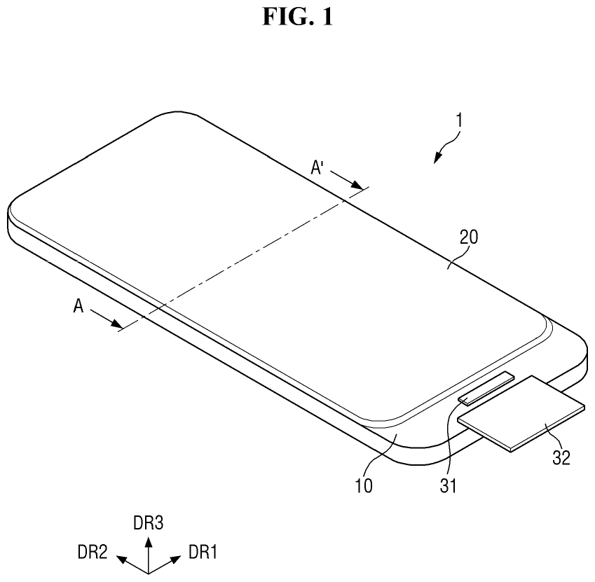

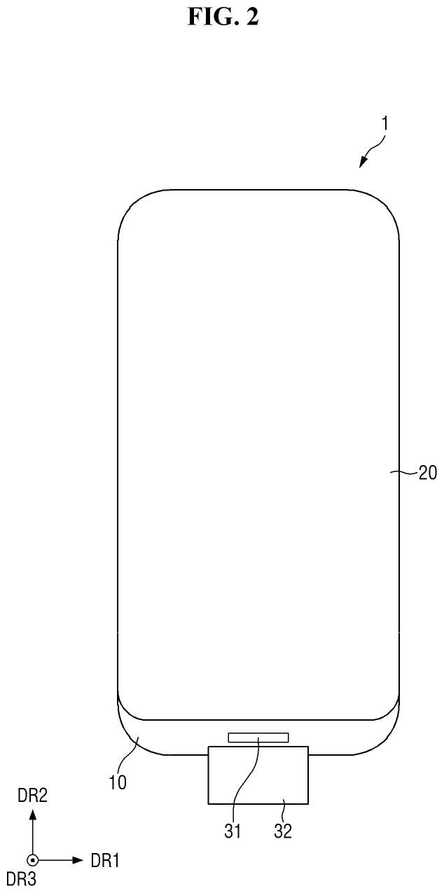

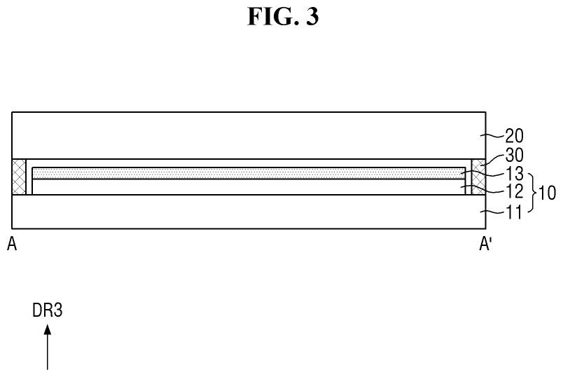

FIG. 1 is a perspective view of a display device 1 according to an embodiment. FIG. 2 is a plan view of the display device 1 of FIG. 1. FIG. 3 is a cross-sectional view of an example of a surface taken along line A-A′ of FIG. 1.

Referring to FIGS. 1 and 2, the display device 1 is a device for displaying moving images or still images. The display device 1 may be utilized as a display screen in portable electronic devices such as mobile phones, smartphones, tablet personal computers (PCs), smart watches, watch phones, mobile communication terminals, electronic notebooks, electronic books, portable multimedia players (PMPs), navigation devices and/or ultra-mobile PCs(UMPCs), as well as in one or more suitable products such as televisions, notebook computers, monitors, billboards and/or Internet of things (IoT) devices.

The display device 1 may be a light emitting display device such as an organic light emitting display device utilizing an organic light emitting diode, a quantum dot light emitting display device including a quantum dot light emitting layer, an inorganic light emitting display device including an inorganic semiconductor, or a micro- or nano-light emitting display device utilizing a micro- or nano-light emitting diode. A case where the display device 1 is an organic light emitting display device will be mainly described. However, the present disclosure is not limited to this case and is also applicable to display devices including an organic insulating material, an organic light emitting material, and a metal material.

The display device 1 may be formed flat, but the present disclosure is not limited thereto. For example, the display device 1 may include curved portions formed at left and right ends and having a constant or varying curvature. In some embodiments, the display device 1 may be formed to be flexible so that it can be curved, bent, folded, or rolled.

The display device 1 may include a transistor array substrate 10.

The display device 1 may further include a cover substrate 20 facing the transistor array substrate 10 and covering a light emitting element layer 13.

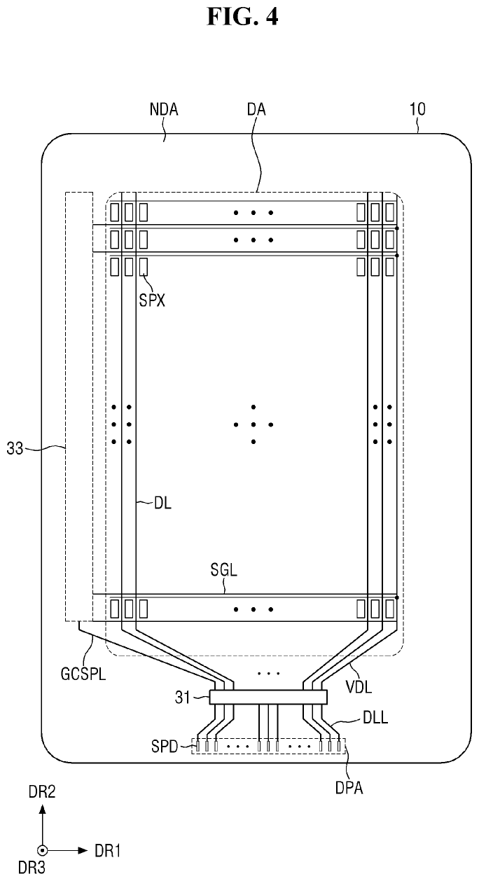

In some embodiments, the display device 1 may further include a display driving circuit 31 for supplying data signals respectively to data lines DL (see FIG. 4) of a circuit layer 12 (see FIG. 3) of the transistor array substrate 10 and a circuit board 32 for supplying one or more suitable signals and power to the transistor array substrate and the display driving circuit 31.

Referring to FIG. 3, the transistor array substrate 10 may include a substrate 11 and the circuit layer 12 disposed on the substrate 11.

The transistor array substrate 10 may further include the light emitting element layer 13 disposed on the circuit layer 12.

For example, the light emitting element layer 13 is disposed between the substrate 11 and the cover substrate 20.

The circuit layer 12 supplies a driving signal of each subpixel corresponding to an image signal to the light emitting element layer 13. The light emitting element layer 13 may be to emit light of each subpixel according to the driving signal. The light of the light emitting element layer 13 may be emitted to the outside through at least one of the substrate 11 and the cover substrate 20. Therefore, the display device 1 can provide a function of displaying an image.

In some embodiments, the display device 1 may further include a touch sensing unit, which senses coordinates of a point touched by a user on a display surface from which light for displaying an image is emitted.

The touch sensing unit may be attached to a surface of the cover substrate or embedded between the transistor array substrate 10 and the cover substrate 20.

The touch sensing unit may include touch electrodes arranged in a touch sensing area corresponding to the display surface and made of a transparent conductive material.

The touch sensing unit may detect whether a touch has been input and coordinates of a point where the touch has been input by periodically sensing changes in capacitance values of the touch electrodes while transmitting touch driving signals to the touch electrodes.

The cover substrate 20 may be bonded to the transistor array substrate 10 to face the transistor array substrate 10.

The cover substrate 20 may be a member for providing rigidity to defend against external physical and electrical shocks. The cover substrate 20 may be made of a transparent material having insulation and rigidity.

In some embodiments, the display device 1 may further include a sealing layer 30 disposed at edges between the transistor array substrate 10 and the cover substrate 20 and bonding the transistor array substrate 10 and the cover substrate 20 together.

In some embodiments, the display device 1 may further include a filling layer filling a space between the transistor array substrate 10 and the cover substrate 20.

As illustrated in FIGS. 1 and 2, the display surface of the display device 1 may have a rectangular shape having short sides in a first direction DR1 and long sides in a second direction DR2 intersecting the first direction DR1. However, this is only an example, and the display surface of the display device 1 may also be implemented in one or more suitable shapes.

For example, the display surface may have a shape in which each corner where a short side extending in the first direction DR1 and a long side extending in the second direction DR2 meet is rounded (substantially rounded) with a set or predetermined curvature. In some embodiments, the display surface may have a polygonal, circular, or elliptical shape.

Although the transistor array substrate 10 is in the form of a flat plate in FIG. 1, the present disclosure is not limited thereto. For example, the transistor array substrate 10 may have a shape in which both ends in the Y-axis direction are bent. In some embodiments, the transistor array substrate 10 may be flexible so that it can be curved, bent, folded, or rolled.

The display driving circuit 31 outputs signals and voltages for driving the transistor array substrate 10.

For example, the display driving circuit 31 may supply data signals to the data lines DL (see FIG. 4) of the transistor array substrate 10 and supply first driving power to a first driving power line VDL (see FIG. 4) of the transistor array substrate 10. In some embodiments, the display driving circuit 31 may supply a scan control signal to a gate driver 33 (see FIG. 4) embedded in the transistor array substrate 10.

The display driving circuit 31 may be provided as an integrated circuit.

An integrated circuit chip of the display driving circuit 31 may be directly mounted on the transistor array substrate 10 utilizing a chip on glass (COG) method, a chip on plastic (COP) method, or an ultrasonic bonding method. In this case, as illustrated in FIG. 2, the integrated circuit chip of the display driving circuit 31 may be disposed in an area of the transistor array substrate 10 which is not covered by the cover substrate 20.

In some embodiments, the integrated circuit chip of the display driving circuit 31 may be mounted on the circuit board 32.

The circuit board 32 may include an anisotropic conductive film. The circuit board 32 may be a flexible printed circuit board, a printed circuit board, or a flexible film such as a chip on film.

The circuit board 32 may be attached to electrode pads of the transistor array substrate 10. Accordingly, lead lines of the circuit board 32 may be electrically connected to the electrode pads of the transistor array substrate 10.

FIG. 4 is a layout view of an example of the circuit layer 12 of FIG. 3.

Referring to FIG. 4, the transistor array substrate 10 may include a display area DA emitting light for displaying an image and a non-display area NDA disposed around the display area DA. The non-display area NDA may be defined as an area extending from edges of the display area DA to edges of the substrate 11 (see FIG. 3).

The transistor array substrate 10 includes subpixels SPX arranged in the display area DA in a matrix in vertical and horizontal directions. Each of the subpixels SPX may be a unit that individually displays its luminance and color.

Pixels may be provided by these subpixels SPX. Each of the pixels may include three or more subpixels SPX that are adjacent to each other and emit light of three or more different colors.

The non-display area NDA may include a display pad area DPA disposed adjacent to an edge of the substrate 11. The transistor array substrate 10 may further include signal pads SPD disposed in the display pad area DPA of the non-display area NDA.

The circuit board 32 may be attached to the display pad area DPA of the transistor array substrate 10 and electrically connected to the signal pads SPD.

The transistor array substrate 10 further includes lines disposed in the display area DA and supplying signals or power to the subpixels SPX. The lines of the transistor array substrate 10 may include scan gate lines SGL, the data lines DL, and the first power line VDL.

The scan gate lines SGL may extend in the first direction DR1 (horizontal direction in FIG. 4).

The data lines DL may extend in the second direction DR2 (vertical direction in FIG. 4).

The first power line VDL may extend in any one of the first direction DR1 and the second direction DR2. For example, the first power line VDL may extend in the second direction DR2, like the data lines DL.

In some embodiments, in order to reduce the resistive-capacitive (RC) delay of first power supply due to the resistance of the first power line VDL, the circuit layer 12 may further include a first power auxiliary line (not illustrated) extending in a direction intersecting the first power line VDL and electrically connected to the first power line VDL.

The scan gate lines SGL transmit scan signals for controlling the transmission of data signals to the subpixels SPX.

The scan gate lines SGL may be connected to the gate driver 33 disposed in a part of the non-display area NDA of the transistor array substrate 10.

The gate driver 33 may be electrically connected to the display driving circuit 31 or at least one of the signal pads SPD through at least one gate control supply line GCSPL.

The gate driver 33 may transmit scan signals to the scan gate lines SGL based on a gate control signal and gate-level power supplied through at least one gate control supply line GCSPL.

In FIG. 4, the gate driver 33 is disposed in a part of the non-display area NDA adjacent to one side (i.e., a left side in FIG. 4) of the display area DA in the first direction DR1. However, this is only an example, and the gate driver 33 may also be disposed in another part of the non-display area NDA adjacent to a right side of the display area DA. In some embodiments, the gate driver 33 may be disposed on both sides of the display area DA in the horizontal direction.

The data lines DL are electrically connected between the display driving circuit 31 and the subpixels SPX and transmit data signals output from the display driving circuit 31 to the subpixels SPX.

The display driving circuit 31 may be electrically connected to some of the signal pads SPD through data connection lines DLL. For example, the display driving circuit 31 may be electrically connected to the circuit board 32 through the data connection lines DLL and some signal pads SPD.

The circuit board 32 may supply digital video data corresponding to an image signal and timing signals to the display driving circuit 31.

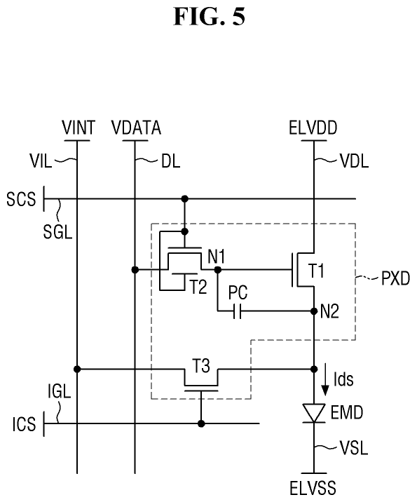

The circuit layer 12 may further include the first power line VDL and a second power line extending from the non-display area NDA to the display area DA and respectively transmitting first power ELVDD (see FIG. 5) and second power ELVSS (see FIG. 5) for driving light emitting elements EMD (see FIG. 5). Here, the second power ELVSS may have a lower voltage level than the first power ELVDD.

Each of the first power line VDL and the second power line may be electrically connected to the display driving circuit 31 or at least one of the signal pads SPD.

The circuit layer 12 includes pixel drivers PXD (see FIG. 5) respectively corresponding to the subpixels SPX and electrically connected to the scan gate lines SGL, the data lines DL and the first power line VDL.

FIG. 5 is an equivalent circuit diagram of an example of a subpixel SPX of FIG. 4.

Referring to FIG. 5, one of the pixel drivers PXD respectively corresponding to the subpixels SPX may be electrically connected to an anode of one of the light emitting elements EMD of the light emitting element layer 13 and may supply a driving current Ids to the light emitting element EMD.

The pixel driver PXD may include one or more thin-film transistors T1 through T3.

For example, the pixel driver PXD may include a first thin-film transistor T1 electrically connected to the light emitting element EMD and a second thin-film transistor T2 electrically connected between a gate electrode of the first thin-film transistor T1 and a data line DL. In some embodiments, the pixel driver PXD may further include a pixel capacitor PC.

In some embodiments, the pixel driver PXD may further include a third thin-film transistor T3 electrically connected between an initialization voltage line VIL for transmitting an initialization voltage VINT and the anode of the light emitting element EMD.

The light emitting element EMD may be an organic light emitting diode including a light emitting layer made of an organic material. In some embodiments, the light emitting element EMD may include a light emitting layer made of an inorganic material. In some embodiments, the light emitting element EMD may be a quantum dot light emitting element including a quantum dot light emitting layer. In some embodiments, the light emitting element EMD may be a micro-light emitting diode.

The first thin-film transistor T1 is connected in series to the light emitting element EMD between a first power line VDL and a second power line VSL. For example, a first electrode (e.g., a drain electrode) of the first thin-film transistor T1 may be electrically connected to the first power line VDL, and a second electrode (e.g., a source electrode) of the first thin-film transistor T1 may be electrically connected to the anode 131 of the light emitting element EMD.

However, the source electrode and the drain electrode of the first thin-film transistor T1 may be changed differently from the example of FIG. 5 according to the structure of the first thin-film transistor T1.

A cathode 134 of the light emitting element EMD may be electrically connected to the second power line VSL.

In some embodiments, the gate electrode of the first thin-film transistor T1 may be electrically connected to the second thin-film transistor T2.

The pixel capacitor PC may be electrically connected between a first node N1 and a second node N2. The first node N1 is a contact point between the gate electrode of the first thin-film transistor T1 and the second thin-film transistor T2. The second node N2 is a contact point between the first thin-film transistor T1 and the light emitting element EMD.

The second thin-film transistor T2 may be electrically connected between the data line DL and the gate electrode of the first thin-film transistor T1 and may be turned on based on a scan signal SCS of a scan gate line SGL.

For example, when the scan signal SCS is supplied through the scan gate line SGL, the second thin-film transistor T2 may be turned on, and the data line DL and the gate electrode of the first thin-film transistor T1 may be electrically connected. At this time, a data signal VDATA of the data line DL may be supplied to the pixel capacitor PC and the gate electrode of the first thin-film transistor T1 through the turned-on second thin-film transistor T2 and the first node N1.

The first thin-film transistor T1 may be turned on when a voltage difference between the gate electrode and the drain electrode becomes greater than a threshold voltage. For example, when the voltage difference between the drain electrode and the gate electrode to which the first power ELVDD and the data signal VDATA are respectively transmitted is greater than the threshold voltage of the first thin-film transistor T1, the first thin-film transistor T1 may be turned on. At this time, the current Ids between the source electrode and the drain electrode of the first thin-film transistor T1 is supplied as a driving current of the light emitting element EMD. In some embodiments, the magnitude of the current Ids between the source electrode and the drain electrode of the first thin-film transistor T1 corresponds to the data signal VDATA. For example, as the driving current Ids corresponding to the data signal VDATA is supplied to the light emitting element EMD, the light emitting element EMD may emit light having a luminance corresponding to the data signal VDATA.

The pixel capacitor PC is electrically connected between the first node N1 and the second node N2. Therefore, the electric potential of the first node N1 may be maintained at the voltage charged in the pixel capacitor PC until the data signal VDATA of a next image frame is supplied.

The third thin-film transistor T3 may be electrically connected between the initialization voltage line VIL and the second node N2. A gate electrode of the third thin-film transistor T3 may be electrically connected to an initialization gate line IGL.

For example, when an initialization control signal ICS is supplied through the initialization gate line IGL, the third thin-film transistor T3 may be turned on, and the initialization voltage line VIL and the second node N2 may be electrically connected. At this time, the initialization voltage VINT of the initialization voltage line VIL may be supplied to the anode 131 of the light emitting element EMD through the turned-on third thin-film transistor T3 and the second node N2. Accordingly, the electric potential of the anode 131 may be initialized to the initialization voltage VINT.

While the pixel driver PXD has a 3T1C structure including the first thin-film transistor T1, the second thin-film transistor T2, the third thin-film transistor T3 and one pixel capacitor PC in FIG. 5, this is only an example. For example, the pixel driver PXD according to an embodiment is not limited to the 3T1C structure illustrated in FIG. 5 and may also be changed differently from the structure illustrated in FIG. 5 as needed. For example, the pixel driver PXD may not include (e.g., may exclude) the third thin-film transistor T3 or may further include a thin-film transistor for initializing the electric potential of the first node N1.

In some embodiments, although one or more thin-film transistors T1 through T3 included in the pixel driver PXD are formed as N-type or kind metal oxide semiconductor field effect transistors (MOSFETs) in FIG. 5, this is only an example. For example, at least one of the thin-film transistors T1 through T3 included in the pixel driver PXD may also instead be a P-type or kind MOSFET.

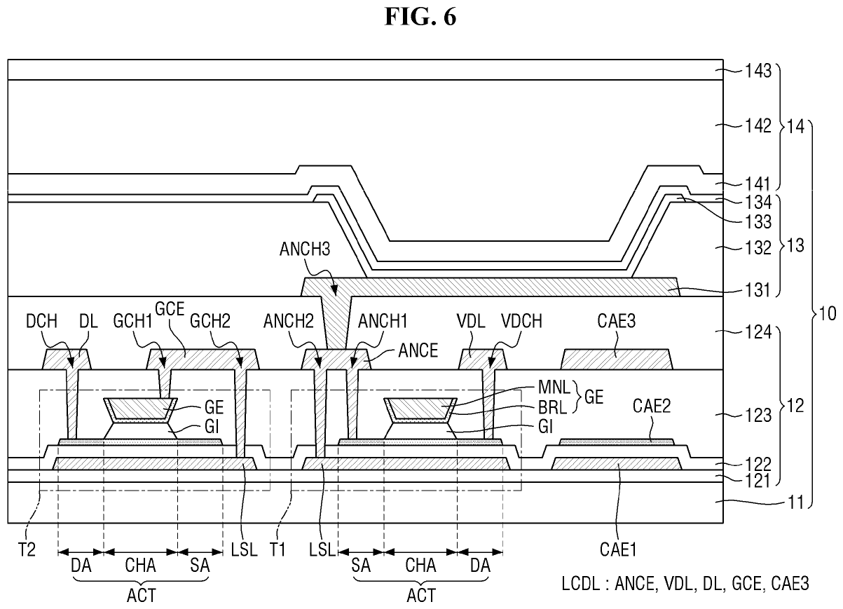

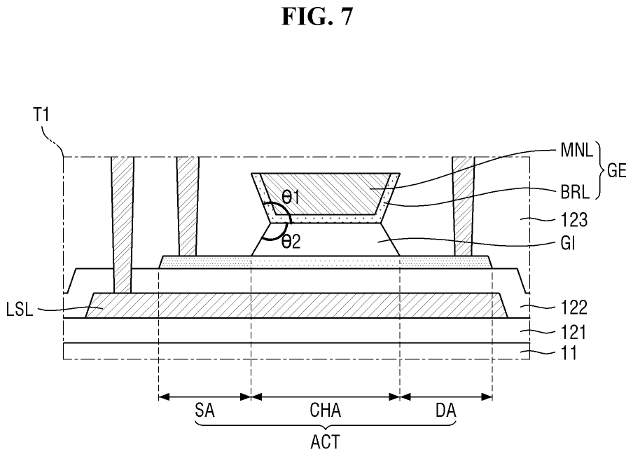

FIG. 6 is a cross-sectional view illustrating a first embodiment of the first thin-film transistor T1, the second thin-film transistor T2, and the pixel capacitor PC in the pixel driver PXD of FIG. 5. FIG. 7 is an enlarged view illustrating a first thin-film transistor T1 of FIG. 6 in more detail.

Referring to FIG. 6, a transistor array substrate 10 according to the first embodiment includes a substrate 11 and a circuit layer 12 disposed on the substrate 11.

The substrate 11 includes a display area DA in which subpixels SPX are arranged, and the circuit layer 12 includes pixel drivers PXD respectively corresponding to the subpixels SPX.

The transistor array substrate 10 may further include a light emitting element layer 13 disposed on the circuit layer 12. The light emitting element layer 13 may include light emitting elements EMD respectively corresponding to the subpixels SPX and respectively electrically connected to the pixel drivers PXD of the circuit layer 12.

In some embodiments, the transistor array substrate 10 may further include a sealing layer 14 disposed on the light emitting element layer 13.

Each of the pixel drivers PXD of the circuit layer 12 may include one or more thin-film transistors T1 and T2. For example, each of the pixel drivers PXD of the circuit layer 12 may include a first thin-film transistor T1 and a second thin-film transistor T2.

According to the first embodiment, the circuit layer 12 may further include an interlayer insulating layer 123 arranged substantially flat on the substrate 11 and covering the first thin-film transistor T1 and the second thin-film transistor T2.

The substrate 11 may be made of a rigid insulating material such as glass.

In some embodiments, the substrate 11 may be made of an insulating material such as polymer resin. For example, the substrate 11 may be made of polyimide.

The substrate 11 may also be a flexible substrate that can be bent, folded, or rolled.

The first thin-film transistor T1 includes an active layer ACT disposed on the substrate 11, a gate insulating layer GI disposed on a channel region CHA of the active layer ACT, and a gate electrode GE disposed on the gate insulating layer GI.

The active layer ACT includes the channel region CHA, a source region SA connected to a side of the channel region CHA, and a drain region DA connected to the other side of the channel region CHA.

The active layer ACT may be made of one semiconductor material selected from polycrystalline silicon, amorphous silicon, and an oxide semiconductor. The oxide semiconductor may include one or more metals selected from indium (In), gallium (Ga), zinc (Zn), tin (Sn), aluminum (Al) and molybdenum (Mo), in addition to oxygen.

When the active layer ACT is made of an oxide semiconductor, the source region SA and the drain region DA may become conductive by including a lower oxygen content (e.g., amount) than the channel region CHA.

The gate insulating layer GI may be a multilayer in which one or more inorganic layers selected from silicon nitride, silicon oxynitride, silicon oxide, titanium oxide, and aluminum oxide are alternately stacked.

The gate electrode GE may include an electrode main layer MNL and an electrode barrier layer BRL. The electrode barrier layer BRL may be disposed between the electrode main layer MNL and the gate insulating layer GI and between side surfaces of the electrode main layer MNL and the interlayer insulating layer 123.

The electrode main layer MNL may be made of a metal material having a relatively low resistivity in order to lower the resistance of the gate electrode GE.

For example, the electrode main layer MNL may include a single layer or a multilayer made of at least one metal material selected from molybdenum (Mo), aluminum (Al), chromium (Cr), gold (Au), titanium (Ti), nickel (Ni), neodymium (Nd), copper (Cu), and alloys of two or more thereof.

The electrode barrier layer BRL may block or reduce diffusion of the metal material of the electrode main layer MNL, in particular, diffusion of the metal material into the channel region CHA of the active layer ACT through the gate insulating layer GI. The electrode barrier layer BRL may include a metal oxide material including one or more metal materials selected from indium (In), gallium (Ga), zinc (Zn), tin (Sn), aluminum (Al), and molybdenum (Mo).

According to the first embodiment, the electrode barrier layer BRL is disposed not only between a lower surface of the electrode main layer MNL and the gate insulating layer GI but also between the side surfaces of the electrode main layer MNL and the interlayer insulating layer 123. Accordingly, because the side surfaces of the electrode main layer MNL are not exposed to oxygen included in the interlayer insulating layer 123, corrosion of edges between the inclined side surfaces and the upper surface of the electrode main layer MNL can be prevented or reduced. Therefore, a change in switching characteristics of the first thin-film transistor T1 can be delayed, and the lifespan of the first thin-film transistor T1 can be improved.

The interlayer insulating layer 123 may be disposed on a second buffer layer 122 and may evenly cover the gate electrode GE and the active layer ACT. For example, the interlayer insulating layer 123 may contact the source region SA and drain region DA of the active layer ACT, side surfaces of the gate insulating layer GI, and upper and side surfaces of the gate electrode GE.

The interlayer insulating layer 123 may be a multilayer in which one or more inorganic layers selected from silicon nitride, silicon oxynitride, silicon oxide, titanium oxide, and aluminum oxide are alternately stacked.

According to the first embodiment, the circuit layer 12 may further include a first buffer layer 121 disposed on the substrate 11, a light blocking layer LSL on the first buffer layer 121, and the second buffer layer 122 covering the light blocking layer LSL.

For example, the first thin-film transistor T1 may further include the light blocking layer LSL which is disposed on the first buffer layer 121 covering the substrate 11 and overlaps at least the channel region CHA of the active layer ACT. Accordingly, the active layer ACT may be disposed on the second buffer layer 122 covering the light blocking layer LSL.

The light blocking layer LSL may include a light blocking metal material. For example, the light blocking layer LSL may include a single layer or a multilayer made of at least one metal material selected from molybdenum (Mo), aluminum (Al), chromium (Cr), gold (Au), titanium (Ti), nickel (Ni), neodymium (Nd), copper (Cu), and alloys of two or more thereof.

Because the second thin-film transistor T2 has substantially the same structure as the first thin-film transistor T1, a redundant description thereof will not be provided.

In some embodiments, although not illustrated in FIG. 6 and/or the like, because a third thin-film transistor T3 has substantially the same structure as the first thin-film transistor T1, a redundant description thereof will not be provided.

Referring to FIG. 7, a slope 81 of each side surface of the gate electrode GE with respect to a boundary surface between the gate insulating layer GI and the gate electrode GE is an obtuse angle (a substantially obtuse angel). For example, a cross section of the gate electrode GE may have an inverted trapezoidal shape.

In some embodiments, due to the influence of the slope 81 of the side surfaces of the gate electrode GE, a slope 82 of each side surface of the gate insulating layer GI with respect to the boundary surface between the gate insulating layer GI and the gate electrode GE is an obtuse angle (a substantially obtuse angel). For example, a cross section of the gate insulating layer GI may have a trapezoidal shape (a substantially trapezoidal shape). Accordingly, a slope of each side surface of the gate insulating layer GI with respect to a boundary surface between the gate insulating layer GI and the active layer ACT may be an acute angle.

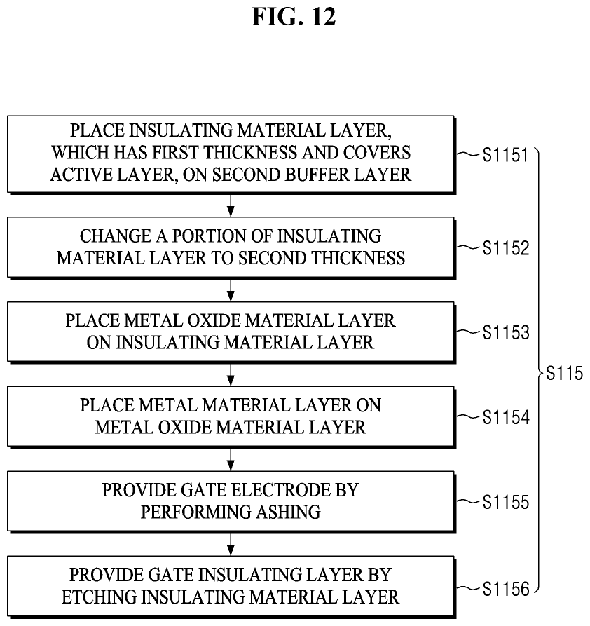

In some embodiments, as will be described later with reference to FIG. 12 and/or the like, the gate electrode GE may be provided through an ashing process so that the cross section of the gate electrode GE can have an inverted trapezoidal shape.

For example, because the gate electrode GE is not provided by a dry etching process, the side surfaces of the gate electrode GE can be prevented or reduced from having a steep slope close to vertical due to the influence of the dry etching process. Therefore, the side surfaces of the gate insulating layer GI may also not have a steep slope close to vertical.

Accordingly, it is possible to prevent or reduce a defect in which the active layer ACT is not completely covered with the interlayer insulating layer 123 due to the steep slope of the side surfaces of the gate insulating layer GI. This can prevent or reduce breaking of the active layer ACT and deterioration of semiconductor characteristics of the active layer ACT, thereby improving the lifespan and uniformity of characteristics of the first thin-film transistor T1.

As illustrated in FIG. 6, the circuit layer 12 of the transistor array substrate 10 according to the first embodiment may further include a wiring conductive layer LCDL disposed on the interlayer insulating layer 123 and a via layer 124 arranged substantially flat on the interlayer insulating layer 123 and covering the wiring conductive layer LCDL.

The wiring conductive layer LCDL may include a data line DL for transmitting a data signal VDATA, a first power line VDL for transmitting first power ELVDD, a gate connection electrode GCE electrically connected to a gate electrode GE of the second thin-film transistor T2, and an anode connection electrode ANCE electrically connected to the source region SA of the active layer ACT of the first thin-film transistor T1.

The anode connection electrode ANCE may be electrically connected to the source region SA of the active layer ACT of the first thin-film transistor T1 and the light blocking layer LSL of the first thin-film transistor T1.

The anode connection electrode ANCE may be electrically connected to the source region SA of the active layer ACT of the first thin-film transistor T1 through a first anode connection hole ANCH1 penetrating the interlayer insulating layer 123.

The anode connection electrode ANCE may be electrically connected to the light blocking layer LSL of the first thin-film transistor T1 through a second anode connection hole ANCH2 penetrating the interlayer insulating layer 123 and the second buffer layer 122.

Accordingly, because the light blocking layer LSL of the first thin-film transistor T1 is electrically connected to the source region SA of the active layer ACT of the first thin-film transistor T1 through the anode connection electrode ANCE, the resistance between the thin-film transistor T1 and a light emitting element EMD may be reduced.

The gate connection electrode GCE may be electrically connected to the gate electrode GE of the second thin-film transistor T2 through a first gate connection hole GCH1 penetrating the interlayer insulating layer 123.

The gate connection electrode GCE may be electrically connected to a light blocking layer LSL of the second thin-film transistor T2 through a second gate connection hole GCH2 penetrating the interlayer insulating layer 123 and the second buffer layer 122.

Accordingly, because the light blocking layer LSL of the second thin-film transistor T2 serves as a bottom gate electrode disposed under an active layer ACT, the second thin-film transistor T2 may be provided as a double-gate structure. Therefore, a characteristic curve of the second thin-film transistor T2 may be gentle. Here, the characteristic curve represents the variation in the magnitude of a drain-source current according to the variation in gate-source voltage.

The data line DL may be electrically connected to a drain region DA of the active layer ACT of the second thin-film transistor T2 through a data connection hole DCH penetrating the interlayer insulating layer 123.

The first power line VDL may be electrically connected to the drain region DA of the active layer ACT of the first thin-film transistor T1 through a power connection hole VDCH penetrating the interlayer insulating layer 123.

The wiring conductive layer LCDL may include a single layer or a multilayer made of at least one metal material selected from molybdenum (Mo), aluminum (Al), chromium (Cr), gold (Au), titanium (Ti), nickel (Ni), neodymium (Nd), copper (Cu), and alloys of two or more thereof.

The via layer 124 may be arranged substantially flat on the interlayer insulating layer 122. The via layer 123 may be made of an organic layer such as acryl resin, epoxy resin, phenolic resin, polyamide resin, or polyimide resin.

The circuit layer 12 may further include a first capacitor electrode CAE1 disposed on the first buffer layer 121, a second capacitor electrode CAE2 disposed on the second buffer layer 122 and overlapping the first capacitor electrode CAE1, and a third capacitor electrode CAE3 disposed on the interlayer insulating layer 123 and overlapping the second capacitor electrode CAE2.

The second capacitor electrode CAE2 may be made of a conductive semiconductor material, like the source region SA and the drain region DA of the active layer ACT.

In one or more embodiments, the first capacitor electrode CAE1 may be connected to the light blocking layer LSL of the first thin-film transistor T1 in a plan view. The second capacitor electrode CAE2 may be electrically connected to the gate electrode GE of the first thin-film transistor T1. In some embodiments, the third capacitor electrode CAE3 may be connected to the anode connection electrode ANCE.

In this case, because the light blocking layer LSL of the first thin-film transistor T1 is electrically connected to the anode connection electrode ANCE, the first capacitor electrode CAE1 and the third capacitor electrode CAE3 correspond to a second node N2, like the source region SA of the active layer ACT of the first thin-film transistor T1. In some embodiments, the second capacitor electrode CAE2 corresponds to a first node N1, like the gate electrode GE of the first thin-film transistor T1.

Accordingly, a pixel capacitor PC may be provided by an overlap area between each of the first capacitor electrode CAE1 and the third capacitor electrode CAE3, the first capacitor electrode and the second capacitor electrode CAE2, and the second capacitor electrode and the third capacitor electrode.

The light emitting element layer 13 includes the light emitting elements EMD respectively corresponding to the subpixels PX. One of the light emitting elements EMD may include an anode 131 and a cathode 134 facing each other and a light emitting layer 133 interposed between the anode 131 and the cathode 134 and made of a photoelectric conversion material.

The light emitting element layer 13 may further include a pixel defining layer 132 covering edges of the anode 131.

The anode 131 may be disposed on the via layer 124, may correspond to each of the subpixels SPX, and may be electrically connected to the anode connection electrode ANCE through a third anode contact hole ANCH3 penetrating the via layer 124.

Accordingly, the anode 131 may be electrically connected to the source region SA of the active layer ACT of the first thin-film transistor T1 through the anode connection electrode ANCE.

The pixel defining layer 132 may be disposed on the via layer 124, may correspond to an area between the subpixels SPX, and may cover the edges of the anode 131.

The pixel defining layer 132 may be arranged substantially flat on via layer 124. The pixel defining layer 132 may be made of an organic layer such as acryl resin, epoxy resin, phenolic resin, polyamide resin, or polyimide resin.

The light emitting layer 133 may be disposed on the anode 131.

The cathode 134 may correspond to the subpixels SPX as a whole and may be disposed on the light emitting layer 133 and the pixel defining layer 132.

The sealing layer 14 is designed to block or reduce penetration of oxygen or moisture into the circuit layer 12 and the light emitting element layer 13 and to protect the circuit layer 12 and the light emitting element layer 13 from physical and electrical shocks caused by foreign substances.

The sealing layer 14 may have a structure in which at least one inorganic layer and at least one organic layer are alternately stacked. For example, the sealing layer 14 may include a first inorganic layer 141 disposed on the light emitting element layer 13 and made of an inorganic insulating material, an organic layer 142 disposed on the first inorganic layer 141 and made of an organic insulating material, and a second inorganic layer 143 disposed on the first inorganic layer 141, covering the organic layer 142 and made of an inorganic insulating material.

As described above, according to the first embodiment, the slope of each side surface of the gate electrode GE and the slope of each side surface of the gate insulating layer GI with respect to the boundary surface between the gate electrode GE and the gate insulating layer GI may each be an obtuse angle (a substantially obtuse angel). For example, the gate electrode GE may have an inverted trapezoidal cross section, and the gate insulating layer GI may have a trapezoidal cross section.

In some embodiments, the slope of each side surface of the gate electrode GE may be relatively gentle because it is not affected by dry etching. Accordingly, the slope of each side surface of the gate insulating layer GI may also be relatively gentle. Therefore, the active layer ACT may be completely covered with the interlayer insulating layer 123 with improved reliability.

Consequently, this can prevent or reduce breaking of the active layer ACT and deterioration of semiconductor characteristics of the active layer ACT, thereby preventing or reducing a reduction in the lifespan and uniformity of characteristics of the thin-film transistors T1 and T2.

The transistor array substrate 10 including the above thin-film transistors T1 and T2 can be easily applied to a high-resolution display device 1 and can induce an improvement in the image quality of the display device 1.

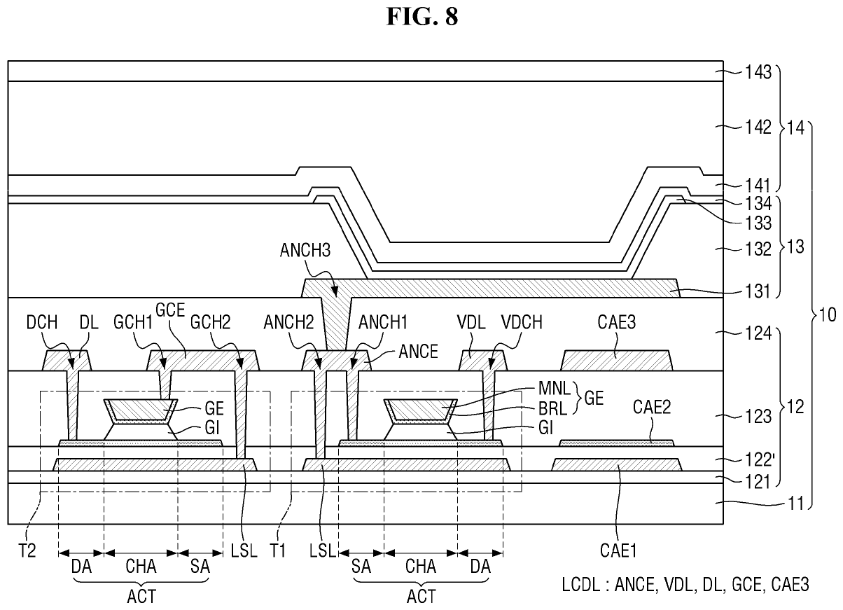

FIG. 8 is a cross-sectional view illustrating a second embodiment of the first thin-film transistor T1, the second thin-film transistor T2, and the pixel capacitor PC in the pixel driver PXD of FIG. 5.

A transistor array substrate 10 according to the second embodiment is substantially the same as the first embodiment of FIGS. 6 and 7 except that a second buffer layer 122′ is arranged substantially flat. Therefore, any redundant description will not be provided.

According to the second embodiment, the second buffer layer 122′ is arranged substantially flat on a first buffer layer 121 and covers light blocking layers LSL and a first capacitor electrode CAE1.

For example, the second buffer layer 122′ according to the second embodiment may be provided by planarizing an insulating material layer stacked on the first buffer layer 121 through an ashing process and/or the like.

According to the second embodiment, because the second buffer layer 122′ is arranged substantially, a breaking or displacement defect of each active layer ACT disposed on the second buffer layer 122′ can be prevented or reduced. Accordingly, the uniformity of characteristics of thin-film transistors T1 and T2 can be improved.

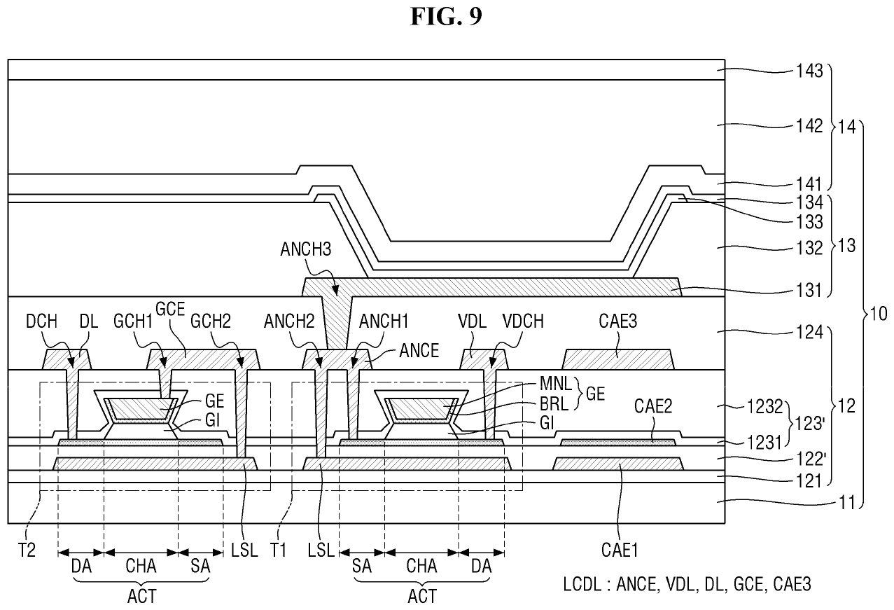

FIG. 9 is a cross-sectional view illustrating a third embodiment of the first thin-film transistor T1, the second thin-film transistor T2, and the pixel capacitor PC in the pixel driver PXD of FIG. 5.

Referring to FIG. 9, a transistor array substrate 10 according to the third embodiment is substantially the same as the first embodiment illustrated in FIGS. 6 and 7 or the second embodiment illustrated in FIG. 8 except that an interlayer insulating layer 123′ includes a first interlayer insulating layer 1231 and a second interlayer insulating layer 1232. Therefore, any redundant description will not be provided.

The first interlayer insulating layer 1231 may be disposed on a second buffer layer 122′ and may contact source regions SA and drain regions DA of active layers ACT, gate insulating layers GI, and gate electrodes GE. The first interlayer insulating layer 1231 may contact side surfaces of the gate insulating layers GI and upper and side surfaces of the gate electrodes GE.

The first interlayer insulating layer 1231 may be disposed to a thickness equal to or greater than a critical thickness at which side surfaces of the active layers ACT, the side surfaces of the gate insulating layers GI, and the side surfaces of the gate electrodes GE are completely covered. Accordingly, the active layers ACT, the gate insulating layers GI, and the gate electrodes GE can be covered with the first interlayer insulating layer 1231 with improved reliability.

The second interlayer insulating layer 1232 is arranged substantially flat on the first interlayer insulating layer 1231.

For example, the second interlayer insulating layer 1232 according to the third embodiment may be provided by planarizing an insulating material layer stacked on the first interlayer insulating layer 1231 through an ashing process and/or the like.

According to the third embodiment, the interlayer insulating layer 123′ can be arranged substantially flat, and the active layers ACT and the gate electrodes GE can be covered with the interlayer insulating layer 123′ with improved reliability.

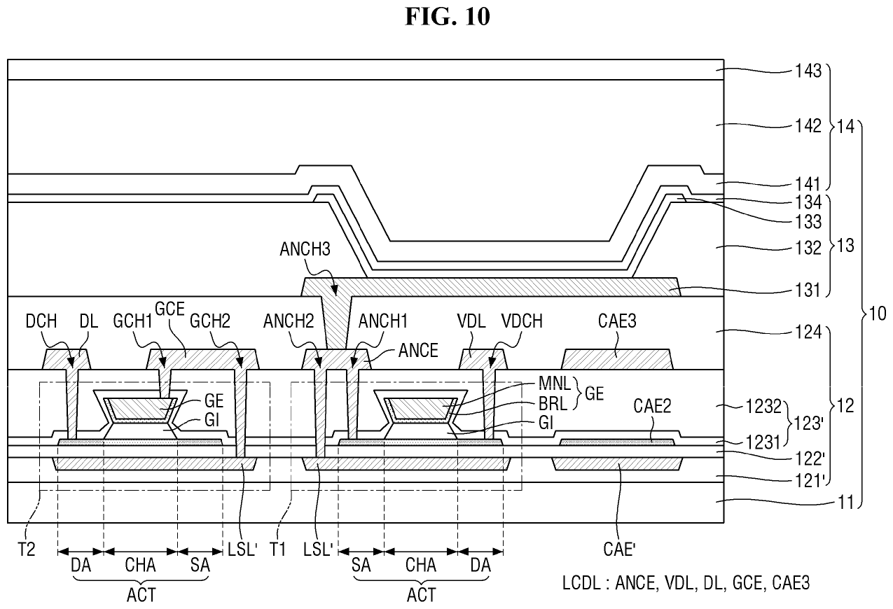

FIG. 10 is a cross-sectional view illustrating a fourth embodiment of the first thin-film transistor T1, the second thin-film transistor T2, and the pixel capacitor PC in the pixel driver PXD of FIG. 5.

Referring to FIG. 10, a transistor array substrate 10 according to the fourth embodiment is substantially the same as the first embodiment illustrated in FIGS. 6 and 7, the second embodiment illustrated in FIG. 8, or the third embodiment illustrated in FIG. 9 except that side surfaces of light blocking layers LSL′ and side surfaces of a first capacitor electrode CAE1′ contact a first buffer layer 121′. Therefore, any redundant description will not be provided.

According to the fourth embodiment, because the light blocking layers LSL′ and the first capacitor electrode CAE1′ are respectively disposed in grooves of the first buffer layer 121′, a step difference due to the light blocking layers LSL′ and the first capacitor electrode CAE1′ can be reduced.

Accordingly, a second buffer layer 122′ may be arranged substantially flatter, which, in turn, further prevents a breaking or displacement defect of each active layer ACT disposed on the second buffer layer 122′.

Next, a method of fabricating a transistor array substrate according to an embodiment will be described.

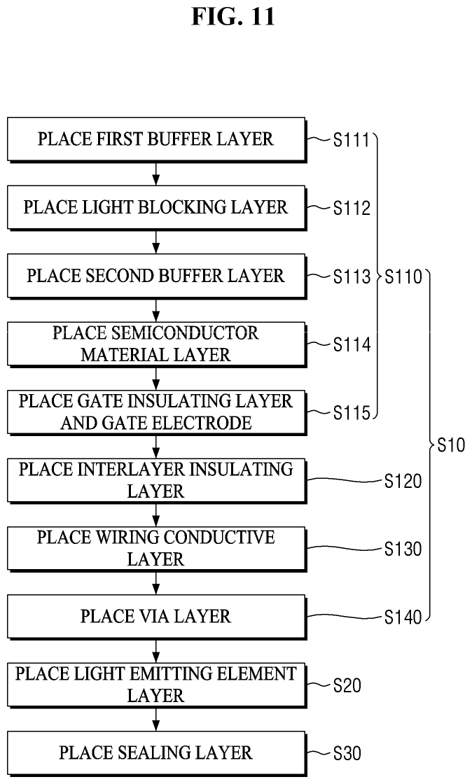

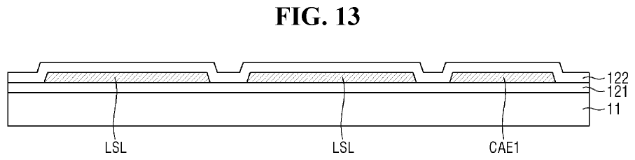

FIG. 11 is a flowchart illustrating a method of fabricating a transistor array substrate according to an embodiment. FIG. 12 is a flowchart illustrating detailed operations in an operation of placing a gate insulating layer and a gate electrode in FIG. 11. FIGS. 13 through 34 are process diagrams illustrating some operations of FIGS. 11 and 12.

Referring to FIG. 11, the method of fabricating the transistor array substrate according to the embodiment includes placing a circuit layer 12, which includes pixel drivers PXD respectively corresponding to subpixels SPX and each including one or more thin-film transistors T1 through T3, on a substrate 11 including a display area DA in which the subpixels SPX are arranged (operation (task or act) S10) and placing a light emitting element layer 13, which includes light emitting elements EMD respectively corresponding to the subpixels SPX and electrically connected to the pixel drivers PXD, respectively, on the circuit layer 12 (operation S20).

In some embodiments, the method of fabricating the transistor array substrate may further include placing a sealing layer 14 on the light emitting element layer 13 (operation S30).

According to an embodiment, the placing of the circuit layer 12 (operation S10) includes placing the thin-film transistors T1 and T2 on the substrate 11 (operation S110) and placing an interlayer insulating layer 123 to cover the thin-film transistors T1 and T2 (operation S120).

In some embodiments, the placing of the circuit layer 12 (operation S10) may further include placing a wiring conductive layer LCDL on the interlayer insulating layer 123 after placing connection holes ANCH1, ANCH2, GCH1, GCH2, DCH and VDCH penetrating at least the interlayer insulating layer 123 among the interlayer insulating layer 123 and a second buffer layer 122 (operation S130) and placing a via layer 124 to cover the wiring conductive layer LCDL (operation S140).

Accordingly, in the placing of the light emitting element layer 13 (operation S20), the light emitting element layer 13 may be placed on the via layer 124.

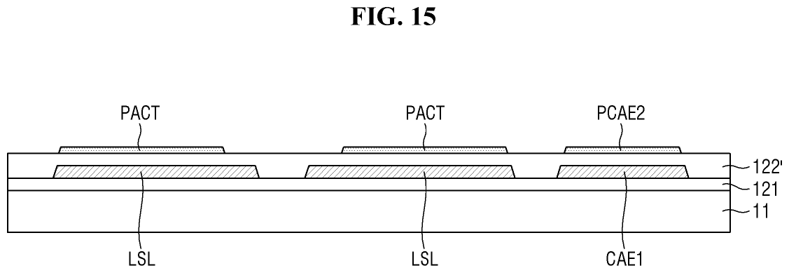

According to an embodiment, the placing of the thin-film transistors T1 and T2 (operation S110) includes placing a first buffer layer 121 on the substrate 11 (operation S111), placing a light blocking layer LSL on the first buffer layer 121 (operation S112), placing the second buffer layer 122, which covers the light blocking layer LSL, on the first buffer layer 121 (operation S113), placing a semiconductor material layer PACT (see FIG. 15) on the second buffer layer 122 (operation S114), and placing a gate insulating layer GI and a gate electrode GE on a portion of the semiconductor material layer PACT (operation S115).

In the placing of the gate insulating layer GI and the gate electrode GE (operation S115), a slope of each side surface of the gate electrode GE with respect to a boundary surface between the gate insulating layer GI and the gate electrode GE is an obtuse angle (a substantially obtuse angel). In some embodiments, a slope of each side surface of the gate insulating layer GI with respect to the boundary surface between the gate insulating layer GI and the gate electrode GE is an obtuse angle (a substantially obtuse angel).

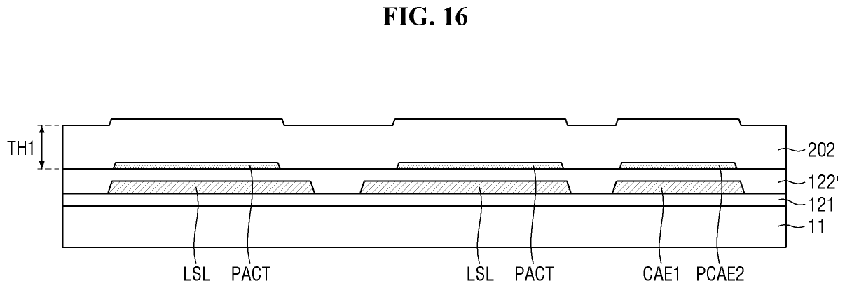

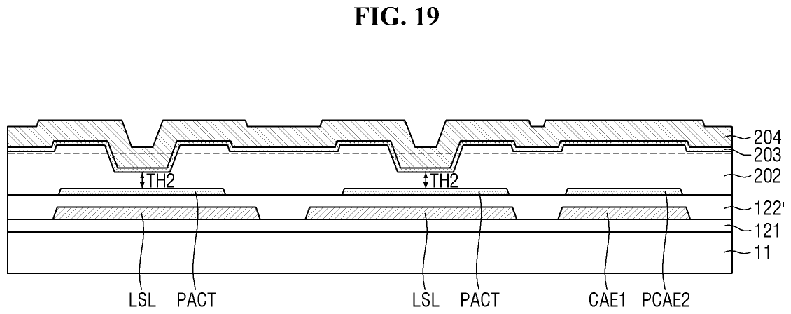

As illustrated in FIG. 12, according to an embodiment, the above shapes of the gate electrode GE and the gate insulating layer GI may result from an etching process performed on an insulating material layer 202 (see FIG. 16) and an ashing process performed on a metal material layer 204 (see FIG. 19) in the placing of the gate insulating layer GI and the gate electrode GE (operation S115).

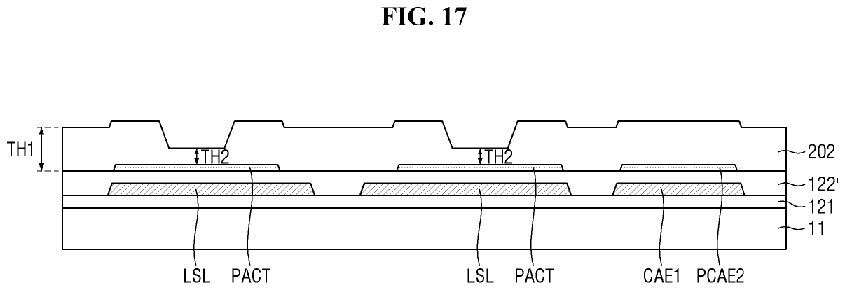

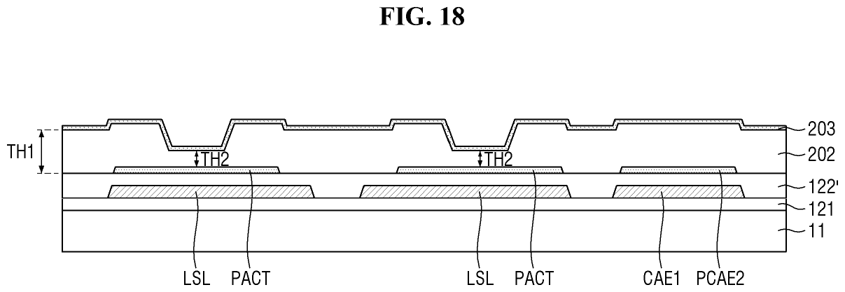

As illustrated in FIG. 12, according to an embodiment, the placing of the gate insulating layer GI and the gate electrode GE (operation S115) may include placing the insulating material layer 202 (see FIG. 16), which has a first thickness TH1 (see FIG. 16) and covers the semiconductor material layer PACT, on the second buffer layer 122 (operation S1151), partially etching the insulating material layer 202 to change a portion of the insulating material layer 202, which overlaps a portion of the semiconductor material layer PACT, to a second thickness TH2 (see FIG. 17) smaller than the first thickness TH1 (operation S1152), placing a metal oxide material layer 203 (see FIG. 18) on the insulating material layer 202 (operation S1153), placing the metal material layer 204 (see FIG. 19) on the metal oxide material layer 203 (operation S1154), providing the gate electrode GE which includes an electrode barrier layer BRL made of the metal oxide material layer 203 remaining on the insulating material layer 202 having the second thickness TH2 and an electrode main layer MNL made of the metal material layer 204 remaining on the electrode barrier layer BRL by performing ashing on the metal material layer 204 and the metal oxide material layer 203 until the insulating material layer 202 having the first thickness TH1 is exposed (operation S1155), and removing the insulating material layer 202 having the first thickness TH1 by etching the insulating material layer 202 and providing the gate insulating layer GI utilizing the insulating material layer 202 having the second thickness TH2 and remaining between the gate electrode GE and the semiconductor material layer PACT (operation S1156).

Referring to FIG. 13, a first buffer layer 121 covering a substrate 11 may be placed by stacking an inorganic insulating material on the substrate 11 (operation S111).

The substrate 11 may be made of an insulating material such as glass.

Then, light blocking layers LSL may be placed by partially etching a light blocking material on the first buffer layer 121 (operation S112).

At this time, a first capacitor electrode CAE1 may be further placed together with the light blocking layers LSL.

The light blocking material may include a single layer or a multilayer made of at least one metal material selected from molybdenum (Mo), aluminum (Al), chromium (Cr), gold (Au), titanium (Ti), nickel (Ni), neodymium (Nd), copper (Cu), and alloys of two or more thereof.

In consideration of high resolution, the etching of the light blocking material may be performed by dry etching having a relatively low process error compared with wet etching.

Next, a second buffer layer 122 covering the light blocking layers LSL and the first capacitor CAE1 may be placed by stacking an inorganic insulating material on the first buffer layer 121, the light blocking layers LSL, and the first capacitor electrode CAE1 (operation S113).

Each of the first buffer layer 121 and the second buffer layer 122 may be a multilayer in which one or more inorganic layers selected from silicon nitride, silicon oxynitride, silicon oxide, titanium oxide, and aluminum oxide are alternately stacked.

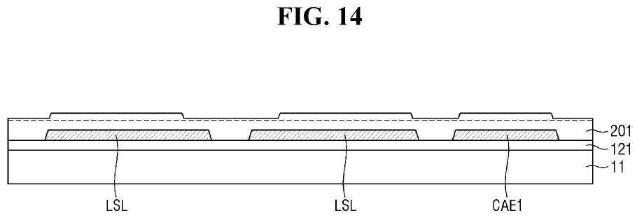

As illustrated in FIG. 14, when the transistor array substrate 10 of the second embodiment is to be provided, the placing of the second buffer layer 122′ (operation S113) may include placing a flat second buffer layer 122′ by performing ashing on an inorganic insulating material 201 stacked on the first buffer layer 121.

Referring to FIG. 15, semiconductor material layers PACT may be placed by partially etching a semiconductor material stacked on the second buffer layer 122′ (operation S114).

The semiconductor material layers PACT are preliminary elements to be formed into active layers ACT of thin-film transistors T1 and T2 by subsequent operations.

Here, a pre-capacitor electrode PCAE2 overlapping the first capacitor electrode CAE1 may be further placed together with the semiconductor material layers PACT. The pre-capacitor electrode PCAE2 is a preliminary element to be formed into a second capacitor electrode CAE2 by subsequent operations.

The semiconductor material may be made of one semiconductor material selected from polycrystalline silicon, amorphous silicon, and an oxide semiconductor. The oxide semiconductor may include one or more metals selected from indium (In), gallium (Ga), zinc (Zn), tin (Sn), aluminum (Al) and molybdenum (Mo), in addition to oxygen.

Referring to FIG. 16, an insulating material layer 202 which covers the semiconductor material layers PACT and has a first thickness TH1 may be placed on the second buffer layer 122′ by stacking an insulating material on the second buffer layer 122′ and the semiconductor material layers PACT (operation S1151).

The insulating material layer 202 may be a multilayer in which one or more inorganic layers selected from silicon nitride, silicon oxynitride, silicon oxide, titanium oxide, and aluminum oxide are alternately stacked.

Referring to FIG. 17, the insulating material layer 202 stacked on the second buffer layer 122′ is partially etched to change a portion of the insulating material layer 202, which overlaps a portion of each semiconductor material layer PACT, to a second thickness TH2 smaller than the first thickness TH1 (operation S1152).

Here, the insulating material layer 202 having the second thickness TH2 may be provided by grooves disposed in the insulating material layer 202 having the first thickness TH1.

Because the grooves of the insulating material layer 202 which correspond to the insulating material layer 202 having the second thickness TH2 become molds of gate electrodes GE by subsequent operations, a difference between the first thickness TH1 and the second thicknesses TH2, that is, a thickness of each groove of the insulating material layer 202 may be equal to or greater than a thickness of each gate electrode GE. In some embodiments, in consideration of a stacking defect of an interlayer insulating layer 123 due to the slope of side surfaces of the gate electrodes GE, the grooves of the insulating material layer 202 which correspond to the insulating material layer 202 having the second thickness TH2 may include side surfaces having a gentle slope.

In some embodiments, in consideration of the ease of an etching process for placing gate insulating layers GI, the grooves of the insulating material layer 202 which correspond to the insulating material layer 202 having the second thickness TH2 may have an inverted (a substantially inverted) trapezoidal cross section.

Referring to FIG. 18, a metal oxide material layer 203 may be placed by stacking a metal oxide material on the insulating material layer 202 including the grooves (operation S1153).

The metal oxide material layer 203 may include one or more metals selected from indium (In), gallium (Ga), zinc (Zn), tin (Sn), aluminum (Al) and molybdenum (Mo), in addition to oxygen. In some embodiments, the metal oxide material layer 203 may have conductivity.

Referring to FIG. 19, a metal material layer 204 may be placed by stacking a metal material on the metal oxide material layer 203 (operation S1154).

The metal material layer 204 may include a single layer or a multilayer made of at least one metal material selected from molybdenum (Mo), aluminum (Al), chromium (Cr), gold (Au), titanium (Ti), nickel (Ni), neodymium (Nd), copper (Cu), and alloys of two or more thereof.

A total thickness of the metal oxide material layer 203 and the metal material layer 204 may be equal to or smaller than the thickness of the grooves in the insulating material layer 202.

Next, ashing may be performed on the metal oxide material layer 203 and the metal material layer 204 until the insulating material layer 202 having the first thickness TH1 is exposed as indicated by a horizontal dotted line of FIG. 19.

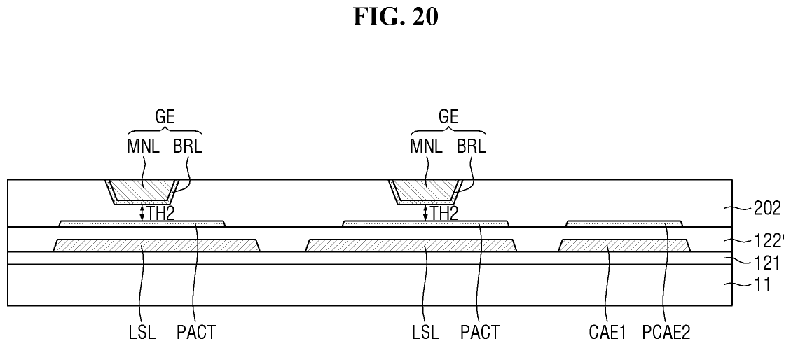

Therefore, as illustrated in FIG. 20, a portion of each of the metal oxide material layer 203 and the metal material layer 204 disposed on the insulating material layer 202 having the first thickness TH1 may be removed. For example, the other portion of each of the metal oxide material layer 203 and the metal material layer 204 may remain in the grooves of the insulating material layer 202 which correspond to the insulating material layer 202 having the second thickness TH2. The remaining metal oxide material layer 203 and the remaining metal material layer 204 may form an electrode barrier layer BRL and an electrode main layer MNL, respectively. Accordingly, the gate electrodes GE, each including the electrode barrier layer BRL and the electrode main layer MNL, may be provided (operation S1155).

The gate electrodes GE may be defined by the grooves of the insulating material layer 202 which correspond to the insulating material layer 202 having the second thickness TH2.

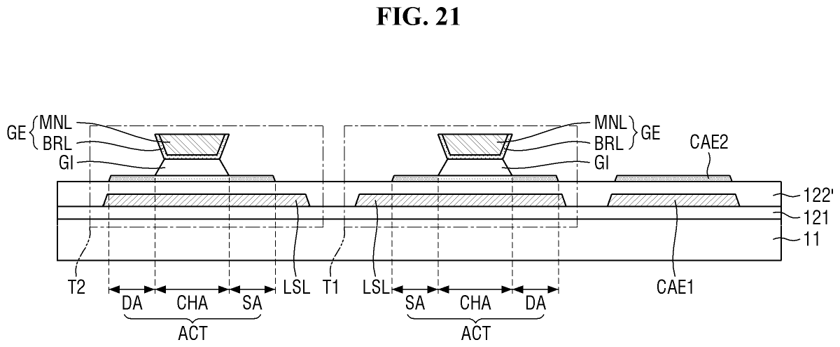

Referring to FIG. 21, the insulating material layer 202 having the first thickness TH1 may be removed by etching the insulating material layer 202 utilizing the gate electrodes GE as a mask. As a result, the insulating material layer 202 having the second thickness TH2 and disposed between the gate electrodes GE and the semiconductor material layers PACT may remain to form the gate insulating layers GI (operation S1156).

In consideration of high resolution, the etching of the insulating material layer 202 may be performed by dry etching having a relatively low process error compared with wet etching.

Here, because side surfaces of the gate electrodes GE have a relatively gentle slope, even when dry etching is performed on the insulating material layer 202, side surfaces of the gate insulating layers GI may have a relatively gentle slope due to the gentle slope of the side surfaces of the gate electrodes GE.

In some embodiments, when the insulating material layer 202 having the first thickness TH1 is removed, each semiconductor material layer PACT excluding a portion overlapping the gate insulating layer GI may be exposed to an etching material for etching the insulating material layer 202 and thus may become conductive.

Accordingly, active layers ACT, each including a channel region CHA, a source region SA and a drain region DA, may be provided. The channel region CHA may be made of a portion of a semiconductor material layer PACT which overlaps a gate electrode GE, and the source region SA and the drain region DA may be respectively made of the other conductive portions of the semiconductor material layer PACT which are disposed at both ends of the channel region CHA.

Accordingly, thin-film transistors T1 and T2, each including the light blocking layer LSL, the active layer ACT and the gate electrode GE, may be placed on the substrate 110 (operation S110).

In some embodiments, when the insulating material layer 202 having the first thickness TH1 is removed, the pre-capacitor electrode PCAE2 is exposed to the etching material and thus becomes conductive. Accordingly, the second capacitor electrode CAE2 may be provided.

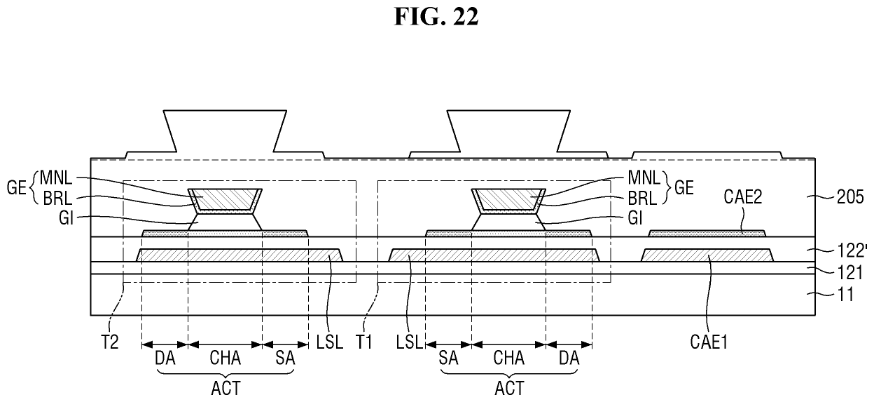

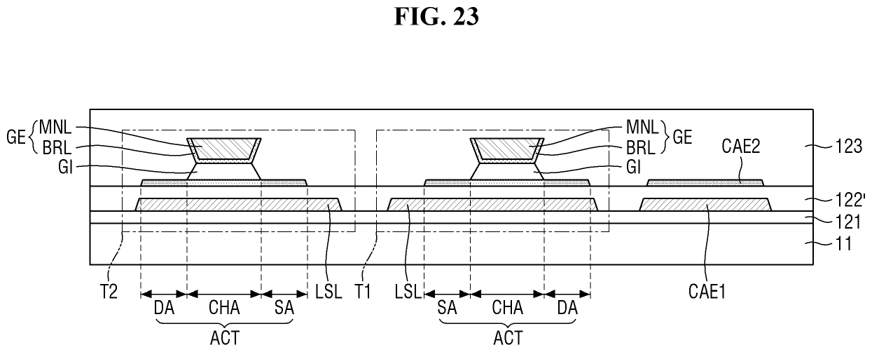

Next, referring to FIGS. 22 and 23, an insulating material 205 is placed on the substrate 11 to cover the thin-film transistors T1 and T2, and then ashing is performed on the insulating material 205 to form a flat interlayer insulating layer 123 (operation S120).

The interlayer insulating layer 123 may contact the source regions SA and the drain regions DA of the active layers ACT of the thin-film transistors T1 and T2, the side surfaces of the gate insulating layers GI, and the upper and side surfaces of the gate electrodes GE.

The interlayer insulating layer 123 may be a multilayer in which one or more inorganic layers selected from silicon nitride, silicon oxynitride, silicon oxide, titanium oxide, and aluminum oxide are alternately stacked.

In some embodiments, when the transistor array substrate 10 of the third embodiment is to be provided, the placing of the interlayer insulating layer 123′ may include placing a first interlayer insulating layer 1231, stacking an insulating material on the first interlayer insulating layer 1231, and providing a flat second interlayer insulating layer 1232 by performing ashing on the insulating material on the first interlayer insulating layer 1231.

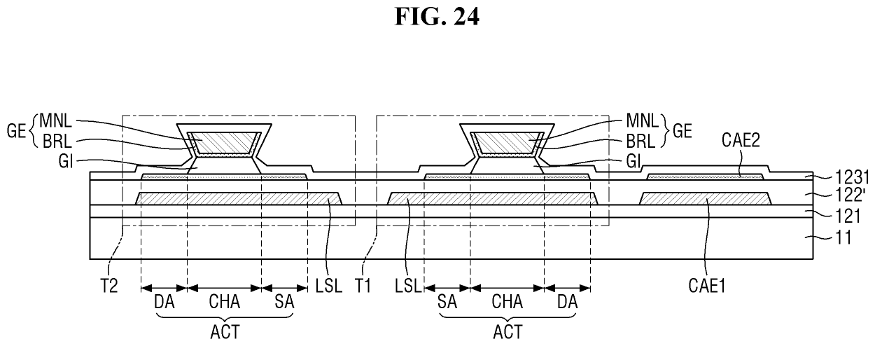

For example, as illustrated in FIG. 24, an insulating material may be stacked on the thin-film transistors T1 and T2 to form the first interlayer insulating layer 1231 which contacts the source regions SA and the drain regions DA of the active layers ACT of the thin-film transistors T1 and T2, the gate insulating layers GI, and the gate electrodes GE.

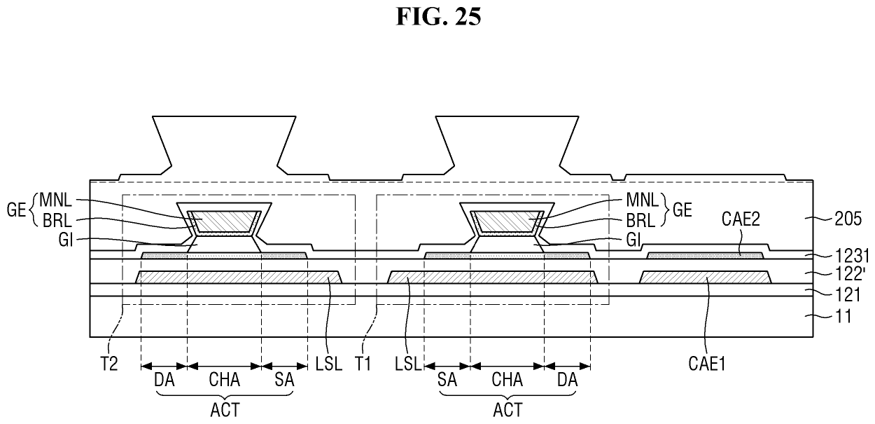

As illustrated in FIG. 25, an insulating material 205 may be stacked on the first interlayer insulating layer 1231, and ashing may be performed on the insulating material 205.

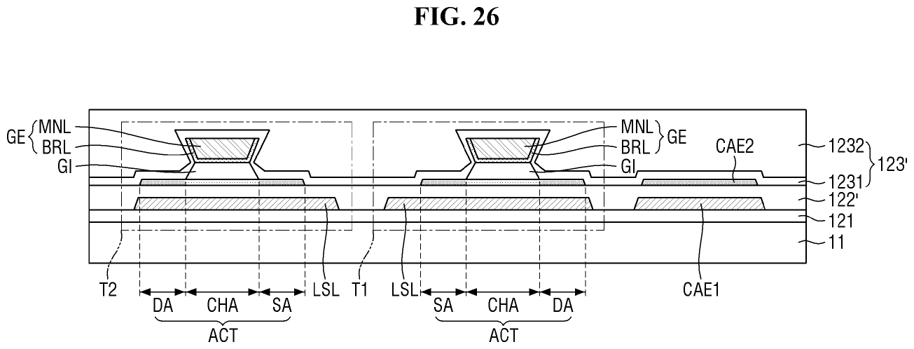

Therefore, as illustrated in FIG. 26, a flat second interlayer insulating layer 1232 may be provided on the first interlayer insulating layer 1231. Accordingly, the interlayer insulating layer 123′ including the first interlayer insulating layer 1231 and the second interlayer insulating layer may be provided.

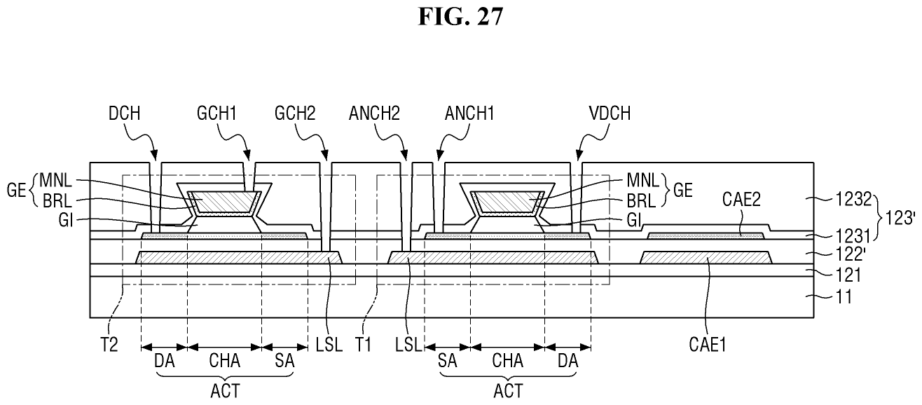

Next, as illustrated in FIG. 27, at least the interlayer insulating layer 123′ among the interlayer insulating layer 123′ and the second buffer layer 122′ may be partially etched to form connection holes ANCH1, ANCH2, GCH1, GCH2, DCH, and VDCH.

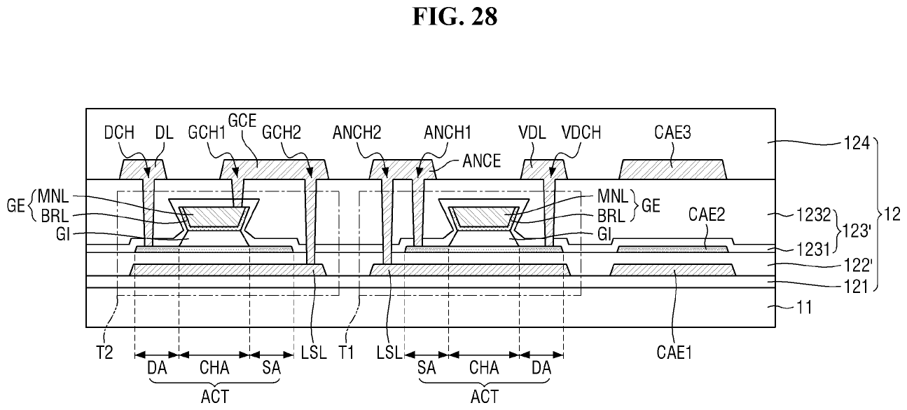

Next, as illustrated in FIG. 28, a conductive material on the interlayer insulating layer 123′ may be partially etched to form a wiring conductive layer LCDL (operation S130).

The wiring conductive layer LCDL may include a data line DL for transmitting a data signal VDATA, a first power line VDL for transmitting first power ELVDD, a gate connection electrode GCE electrically connected to the gate electrode GE of a second thin-film transistor T2, an anode connection electrode ANCE electrically connected to the source region SA of the active layer ACT of a first thin-film transistor T1, and a third capacitor electrode CAE3 overlapping the second capacitor electrode CAE2.

As illustrated in FIG. 28, an insulating material may be stacked on the interlayer insulating layer 123′ to form a flat via layer 124, which covers the wiring conductive layer LCDL, on the interlayer insulating layer 123′ (operation S140).

The via layer 124 may be made of an organic layer such as acryl resin, epoxy resin, phenolic resin, polyamide resin, or polyimide resin.

Accordingly, the circuit layer 12 including the thin-film transistors T1 and T2, the interlayer insulating layer 123′, the wiring conductive layer LCDL, and the via layer 124 may be placed on the substrate 11 (operation S10).

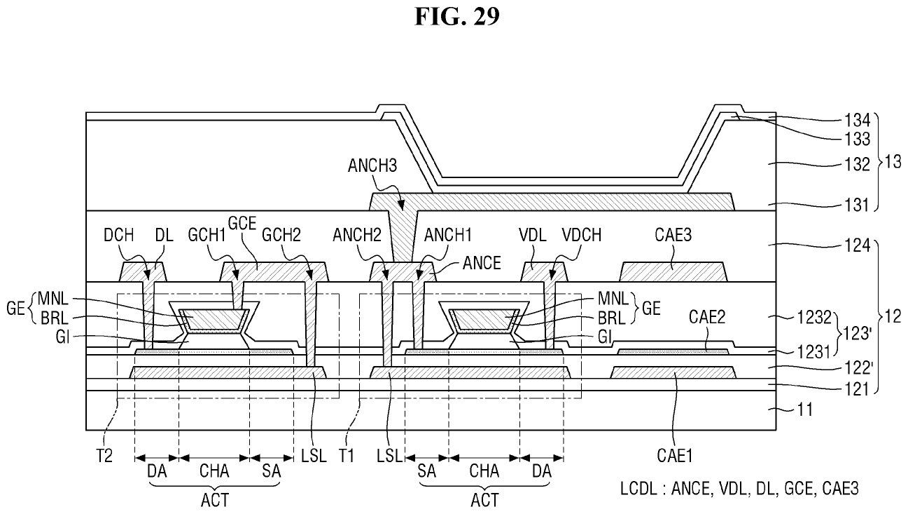

Next, referring to FIG. 29, a light emitting element layer 13 including an anode 131, a pixel defining layer 132, a light emitting layer 133, and a cathode 134 may be placed on the via layer 124 of the circuit layer 12 (operation S20).

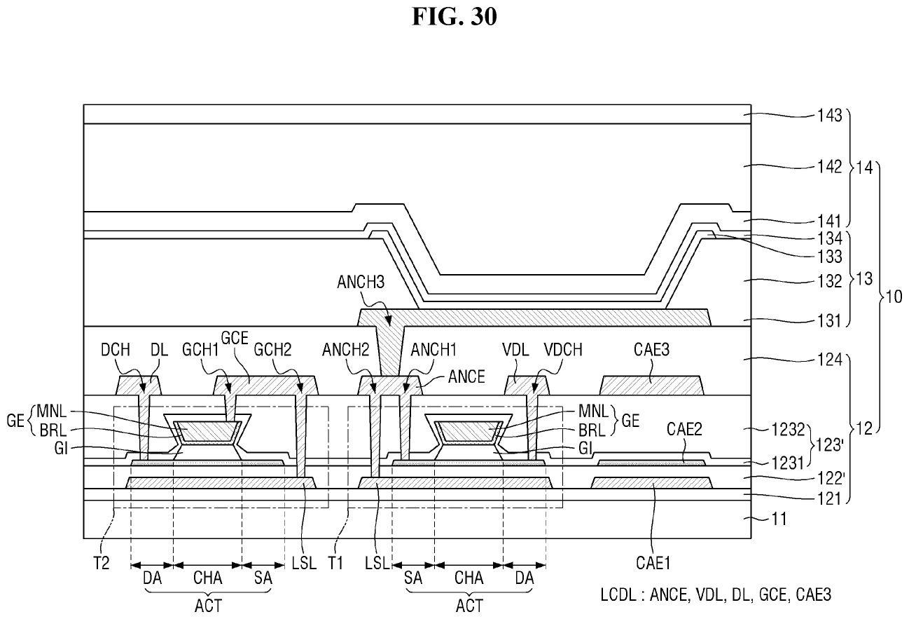

Next, referring to FIG. 30, a sealing layer 14 including a first inorganic layer 141, an organic layer 142, and a second inorganic layer 143 may be placed on the light emitting element layer 13 (operation S30).

When the transistor array substrate 10 of the fourth embodiment is to be provided, the light blocking layers LSL may be provided through an ashing process rather than an etching process on a metal material.

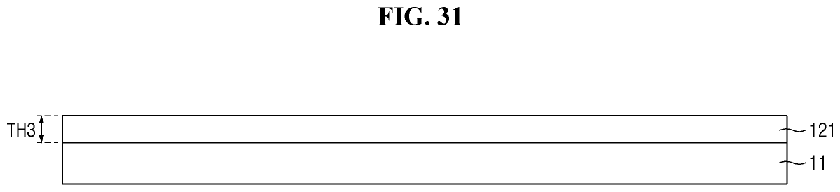

For example, referring to FIG. 31, in the placing of the first buffer layer 121 (operation S111), the first buffer layer 121 may have a third thickness TH3.

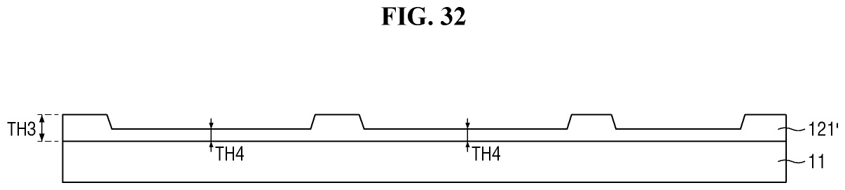

Referring to FIG. 32, the first buffer layer 121 may be partially etched to change a portion of the first buffer layer 121′ to a fourth thickness TH4 smaller than the third thickness TH3.

Here, the first buffer layer 121′ having the fourth thickness TH4 may be provided by grooves disposed in the first buffer layer 121′ having the third thickness TH3.

The grooves of the first buffer layer 121′ which correspond to the first buffer layer 121′ having the fourth thickness TH4 become molds of the light blocking layers LSL and the first capacitor electrode CAE1 by subsequent operations. Therefore, a difference between the third thickness TH3 and the fourth thickness TH4, that is, a thickness of each groove of the first buffer layer 121′ may be equal to or greater than a thickness of each light blocking layer LSL.

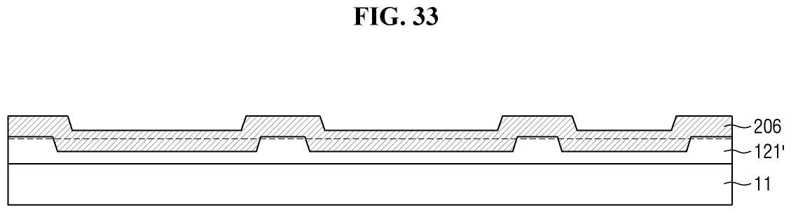

Next, referring to FIG. 33, a light blocking material layer 206 may be placed on the first buffer layer 121′.

Next, ashing may be performed on the light blocking material layer 206 until the first buffer layer 121′ having the third thickness TH3 is exposed as indicated by a horizontal dotted line of FIG. 33.

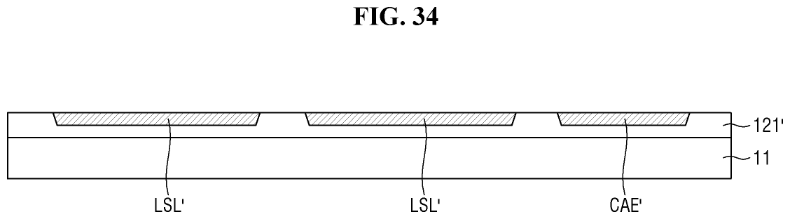

Therefore, as illustrated in FIG. 34, a portion of the light blocking material layer 206 which is disposed on the first buffer layer 121′ having the third thickness TH3 may be removed, and the other portion of the light blocking material layer 206 may remain in the grooves of the first buffer layer 121′ which correspond to the first buffer layer 121′ having the fourth thickness TH4. Accordingly, the light blocking layers LSL′ and the first capacitor electrode CAE1′ may be provided.

Side surfaces of each of the light blocking layers LSL′ and the first capacitor electrode CAE1′ provided by the etching of the first buffer layer 121 and the ashing of the light blocking material layer 206 may contact the first buffer layer 121′.

As described above, in the method of fabricating the transistor array substrate according to the embodiment, dry etching of a metal material is not performed when the gate electrodes GE are placed. Therefore, the side surfaces of the gate electrodes GE can be prevented or reduced from having a steep slope close to vertical. Hence, even when dry etching is utilized to place the gate insulating layers GI, the side surfaces of the gate insulating layers GI can be prevented or reduced from having a steep slope close to vertical due to the influence of the slope of the side surfaces of the gate electrodes GE. Accordingly, a stacking defect of the interlayer insulating layer 123 due to the slope of the side surfaces of the gate insulating layers GI can be prevented or reduced, which, in turn, prevents a reduction in the lifespan and uniformity of characteristics of the thin-film transistors T1 and T2.

Therefore, it is possible to provide the thin-film transistors T1 and T2 which can have reduced resistance because the gate electrodes GE are made of a metal material and can avoid a reduction in lifespan and uniformity of characteristics due to the stacking defect of the interlayer insulating layer 123.

A thin-film transistor according to an embodiment includes an active layer disposed on a substrate, a gate insulating layer disposed on a channel region of the active layer, and a gate electrode disposed on the gate insulating layer. Here, a slope of each side surface of the gate electrode and a slope of each side surface of the gate insulating layer with respect to a boundary surface between the gate insulating layer and the gate electrode are obtuse angles (substantially obtuse angles).

Because each side surface of the gate insulating layer has a slope of an obtuse angle (a substantially obtuse angel) with respect to the boundary surface between the gate insulating layer and the gate electrode, it may have a slope of an acute angle with respect to a boundary surface between the gate insulating layer and the active layer.

According to an embodiment, in a method of fabricating a transistor array substrate including a thin-film transistor, an operation of placing the thin-film transistor on a substrate includes placing a first buffer layer on the substrate, placing a light blocking layer on the first buffer layer, placing a second buffer layer to cover the light blocking layer, placing a semiconductor material layer on the second buffer layer, and placing a gate insulating layer and a gate electrode on a portion of the semiconductor material layer.

The placing of the gate insulating layer and the gate electrode may include placing an insulating material layer, which has a first thickness and covers the semiconductor material layer, on the second buffer layer, changing a thickness of a portion of the insulating material layer to a second thickness smaller than the first thickness, placing a metal oxide material layer on the insulating material layer, placing a metal material layer on the metal oxide material layer, providing the gate electrode which includes an electrode barrier layer made of the metal oxide material layer remaining on the insulating material layer having the second thickness and an electrode main layer made of the metal material layer remaining on the electrode barrier layer by performing ashing on the metal material layer and the metal oxide material layer until the insulating material layer having the first thickness is exposed, and removing the insulating material layer having the first thickness by etching the insulating material layer and providing the gate insulating layer utilizing the insulating material layer having the second thickness and remaining between the gate electrode and the semiconductor material layer. In the providing of the gate insulating layer, an active layer including a channel region made of a portion of the semiconductor material layer which overlaps the gate electrode and a source region and a drain region respectively made of other portions of the semiconductor material layer which are disposed at both ends of the channel region may be provided.

According to an embodiment, the providing of the gate electrode in the placing of the gate insulating layer and the gate electrode includes a process of performing ashing until the metal oxide material layer and the metal material layer disposed on the insulating material layer having the second thickness remain. In other words, the providing of the gate electrode does not include a process of etching a metal material. Accordingly, side surfaces of the gate electrode can be prevented or reduced from having a steep slope close to vertical due to dry etching of the metal material layer.

In some embodiments, a slope of each side surface of the gate electrode corresponds to a slope of each side surface of a portion of the second buffer layer changed to the second thickness. Accordingly, because the slope of a portion of the second buffer layer can be adjusted in the changing of the portion of the second buffer layer to the second thickness, the slope of each side surface of the gate electrode can be adjusted relatively easily.

Thus, in the etching of the insulating material layer during the providing of the gate insulating layer, side surfaces of the gate insulating layer may have a relatively gentle slope due to the relatively gentle slope of the side surfaces of the gate electrode. For example, even when dry etching is performed on the insulating material layer, the side surfaces of the gate insulating layer can be prevented or reduced from having a steep slope close to vertical.

Therefore, generation of gaps or cracks in an interlayer insulating layer due to the steep slope of the gate insulating layer can be prevented or reduced. Accordingly, because the active layer can be completely covered with the interlayer insulating layer, it is possible to prevent or reduce breaking of the active layer and deterioration of semiconductor characteristics of the active layer, thereby preventing or reducing a reduction in the lifespan and uniformity of characteristics of the thin-film transistor.

A transistor array substrate including the above thin-film transistor can be easily applied to a high-resolution display device and can have a beneficial effect on improving the image quality of the display device.

The apparatus, device and/or any other relevant devices or components according to embodiments of the present invention described herein may be implemented utilizing any suitable hardware, firmware (e.g. an application-specific integrated circuit), software, or a combination of software, firmware, and hardware. For example, the various components of the apparatus may be formed on one integrated circuit (IC) chip or on separate IC chips. Further, the various components of the apparatus may be implemented on a flexible printed circuit film, a tape carrier package (TCP), a printed circuit board (PCB), or formed on one substrate. Further, the various components of the apparatus may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A thin-film transistor comprising:
an active layer on a substrate and comprising a channel region, a source region connected to a side of the channel region, and a drain region connected to a different side of the channel region;
a gate insulating layer on the channel region of the active layer; and
a gate electrode on the gate insulating layer,
wherein
a slope of each side surface of the gate electrode with respect to a boundary surface between the gate insulating layer and the gate electrode is an obtuse angle, and
a slope of each side surface of the gate insulating layer with respect to the boundary surface between the gate insulating layer and the gate electrode is an obtuse angle.

2. The thin-film transistor of claim 1, wherein
the active layer and the gate electrode are covered with an interlayer insulating layer arranged substantially flat on the substrate, and
the gate electrode comprises:
an electrode main layer; and
an electrode barrier layer between the electrode main layer and the gate insulating layer and between side surfaces of the electrode main layer and the interlayer insulating layer.

3. The thin-film transistor of claim 2, wherein
The electrode main layer comprises a single layer or a multilayer comprising at least one metal material selected from molybdenum (Mo), aluminum (Al), chromium (Cr), gold (Au), titanium (Ti), nickel (Ni), neodymium (Nd), copper (Cu), and alloys of two or more thereof, and
the electrode barrier layer comprises a metal oxide material comprising one or more metal materials selected from indium (In), gallium (Ga), zinc (Zn), tin (Sn), aluminum (Al) and molybdenum (Mo).

4. The thin-film transistor of claim 2, wherein
the active layer comprises an oxide semiconductor material comprising one or more metal materials selected from indium (In), gallium (Ga), zinc (Zn), tin (Sn), aluminum (Al) and molybdenum (Mo), and
each of the source region and the drain region in the active layer is a conductor.

5. The thin-film transistor of claim 2, wherein the interlayer insulating layer comprises:
a first interlayer insulating layer contacting the source region of the active layer, the drain region of the active layer, the gate insulating layer, and the gate electrode; and
a second interlayer insulating layer arranged substantially flat on the first interlayer insulating layer.

6. The thin-film transistor of claim 2, further comprising a light blocking layer on a first buffer layer covering the substrate and overlapping at least the channel region of the active layer,
wherein the active layer is on a second buffer layer covering the light blocking layer.

7. The thin-film transistor of claim 6, wherein the second buffer layer is arranged substantially flat.

8. The thin-film transistor of claim 6, wherein side surfaces of the light blocking layer contact the first buffer layer.

9. The thin-film transistor of claim 6, wherein the light blocking layer comprises a single layer or a multilayer comprising at least one metal material selected from molybdenum (Mo), aluminum (Al), chromium (Cr), gold (Au), titanium (Ti), nickel (Ni), neodymium (Nd), copper (Cu), and alloys of two or more thereof.

10. A transistor array substrate comprising:
a substrate comprising a display area comprising subpixels; and
a circuit layer on the substrate and comprising pixel drivers respectively corresponding to the subpixels,
wherein each of the pixel drivers comprises at least one thin-film transistor, and
wherein at least one thin-film transistor of the circuit layer comprises:
an active layer on the substrate and comprising a channel region, a source region connected to a side of the channel region, and a drain region connected to a different side of the channel region;
a gate insulating layer on the channel region of the active layer; and
a gate electrode on the gate insulating layer,
wherein
a slope of each side surface of the gate electrode with respect to a boundary surface between the gate insulating layer and the gate electrode is an obtuse angle, and
a slope of each side surface of the gate insulating layer with respect to the boundary surface between the gate insulating layer and the gate electrode is an obtuse angle.

11. The transistor array substrate of claim 10, wherein
the circuit layer further comprises an interlayer insulating layer covering the active layer and the gate electrode and arranged substantially flat on the substrate, and
the gate electrode comprises:
an electrode main layer; and
an electrode barrier layer between the electrode main layer and the gate insulating layer and between a side surface of the electrode main layer and a side surface of the interlayer insulating layer.

12. The transistor array substrate of claim 11, wherein
the electrode main layer comprises a single layer or a multilayer comprising at least one metal material selected from molybdenum (Mo), aluminum (Al), chromium (Cr), gold (Au), titanium (Ti), nickel (Ni), neodymium (Nd), copper (Cu), and alloys of two or more thereof, and
the electrode barrier layer comprises a metal oxide material comprising one or more metal materials selected from indium (In), gallium (Ga), zinc (Zn), tin (Sn), aluminum (Al) and molybdenum (Mo).

13. The transistor array substrate of claim 11, wherein the interlayer insulating layer comprises:
a first interlayer insulating layer contacting the source region of the active layer, the drain region of the active layer, the gate insulating layer, and the gate electrode; and
a second interlayer insulating layer arranged substantially flat on the first interlayer insulating layer.

14. The transistor array substrate of claim 11, wherein
one thin-film transistor of the circuit layer further comprises a light blocking layer on a first buffer layer covering the substrate and overlapping at least the channel region of the active layer, and
the active layer is on a second buffer layer covering the light blocking layer.

15. The transistor array substrate of claim 14, wherein the second buffer layer is arranged substantially flat.

16. The transistor array substrate of claim 14, wherein side surfaces of the light blocking layer contact the first buffer layer.

17. The transistor array substrate of claim 14, further comprising a light emitting element layer on the circuit layer and comprising light emitting elements electrically connected to the pixel drivers,
wherein one of the pixel drivers is configured to transmit a driving current to one of the light emitting elements and comprises:
a first thin-film transistor connected in series to the light emitting element between a first power line and a second power line configured to transmit first power and second power for driving the light emitting elements;
a second thin-film transistor electrically connected between a data line configured to transmit a data signal and a gate electrode of the first thin-film transistor and configured to be turned on based on a scan signal of a scan gate line; and
a pixel capacitor electrically connected to a first node between the gate electrode of the first thin-film transistor and the second thin-film transistor and a second node between the first thin-film transistor and the light emitting element,
wherein
a first electrode of the first thin-film transistor is electrically connected to the first power line, and
a second electrode of the first thin-film transistor is electrically connected to an anode of the light emitting element.

18. The transistor array substrate of claim 17, wherein the circuit layer further comprises:
a wiring conductive layer on the interlayer insulating layer; and
a via layer arranged substantially flat on the interlayer insulating layer and covering the wiring conductive layer,
wherein the wiring conductive layer comprises:
the data line;
the first power line;
a gate connection electrode electrically connecting a gate electrode of the second thin-film transistor and a light blocking layer of the second thin-film transistor; and
an anode connection electrode electrically connected to a source region of an active layer of the first thin-film transistor and a light blocking layer of the first thin-film transistor, and
wherein the anode is on the via layer and electrically connected to the anode connection electrode.

19. The transistor array substrate of claim 18, wherein the circuit layer further comprises:
a first capacitor electrode on the first buffer layer;
a second capacitor electrode on the second buffer layer and overlapping the first capacitor electrode; and
a third capacitor electrode on the interlayer insulating layer and overlapping the second capacitor electrode,
wherein the pixel capacitor is in an overlap area between each of the first capacitor electrode and the third capacitor electrode, the first capacitor electrode and the second capacitor electrode, and the second capacitor electrode and the third capacitor electrode.

20. A method of fabricating a transistor array substrate, the method comprising:
placing a circuit layer, which comprises pixel drivers respectively corresponding to subpixels and each comprising at least one thin-film transistor, on a substrate comprising a display area in which the subpixels are arranged; and
placing a light emitting element layer comprising light emitting elements respectively corresponding to the subpixels and electrically connected to the pixel drivers, respectively, on the circuit layer,
wherein the placing of the circuit layer comprises:
placing a thin-film transistor on the substrate; and
placing an interlayer insulating layer covering the thin-film transistor, on the substrate,
wherein the placing of the thin-film transistor comprises:
placing a first buffer layer on the substrate;
placing a light blocking layer on the first buffer layer;
placing a second buffer layer covering the light blocking layer, on the first buffer layer;
placing a semiconductor material layer on the second buffer layer; and
placing a gate insulating layer and a gate electrode on a portion of the semiconductor material layer, and
wherein
a slope of each side surface of the gate electrode with respect to a boundary surface between the gate insulating layer and the gate electrode is an obtuse angle, and
a slope of each side surface of the gate insulating layer with respect to the boundary surface between the gate insulating layer and the gate electrode is an obtuse angle.

21. The method of claim 20, wherein in the placing of the gate insulating layer and the gate electrode, the gate electrode comprises:
an electrode main layer; and
an electrode barrier layer between the electrode main layer and the gate insulating layer and between a side surface of the electrode main layer and a side surface of the interlayer insulating layer.

22. The method of claim 20, wherein the placing of the gate insulating layer and the gate electrode comprises:
placing an insulating material layer having a first thickness and covering the semiconductor material layer on the second buffer layer;
partially etching the insulating material layer to change a portion of the insulating material layer overlapping a portion of the semiconductor material layer to a second thickness smaller than the first thickness;
placing a metal oxide material layer on the insulating material layer;
placing a metal material layer on the metal oxide material layer;
providing the gate electrode comprising an electrode barrier layer and an electrode main layer, wherein the electrode barrier layer comprises the metal oxide material layer remaining on the insulating material layer having the second thickness, and the electrode main layer comprises the metal material layer remaining on the electrode barrier layer, by performing ashing on the metal material layer and the metal oxide material layer until the insulating material layer having the first thickness is exposed; and
removing the insulating material layer having the first thickness and providing the gate insulating layer comprising the insulating material layer having the second thickness and remaining between the gate electrode and the semiconductor material layer by etching the insulating material layer,
wherein
in the providing of the gate electrode, the electrode barrier layer is placed between the electrode main layer and the gate insulating layer and surrounds the side surfaces of the electrode main layer, and
in the providing of the gate insulating layer, an active layer is provided, wherein the active layer comprises a channel region comprising a portion of the semiconductor material layer overlapping the gate electrode and a source region and a drain region respectively comprising one or more portions of the semiconductor material layer at both ends of the channel region.

23. The method of claim 22, wherein
the metal oxide material layer comprises a metal oxide material comprising one or more metal materials selected from indium (In), gallium (Ga), zinc (Zn), tin (Sn), aluminum (Al) and molybdenum (Mo), and
the metal material layer comprises a single layer or a multilayer comprising at least one metal material selected from molybdenum (Mo), aluminum (Al), chromium (Cr), gold (Au), titanium (Ti), nickel (Ni), neodymium (Nd), copper (Cu), and alloys of two or more thereof.

24. The method of claim 22, wherein the placing of the interlayer insulating layer comprises:
placing a first interlayer insulating layer contacting the source region of the active layer, the drain region of the active layer, the gate insulating layer, and the gate electrode;
stacking an insulating material on the first interlayer insulating layer; and
providing a flat second interlayer insulating layer by performing ashing on the insulating material stacked on the first interlayer insulating layer.

25. The method of claim 22, wherein the placing of the second buffer layer comprises providing a second buffer layer arranged substantially flat on the first buffer layer, by performing ashing on an insulating material stacked on the first buffer layer.

26. The method of claim 22, wherein
in the placing of the first buffer layer, the first buffer layer has a third thickness, and
the placing of the light blocking layer comprises:
partially etching the first buffer layer to change a portion of the first buffer layer to a fourth thickness smaller than the third thickness;
placing a light blocking material layer on the first buffer layer; and
performing ashing on the light blocking material layer until the first buffer layer having the third thickness is exposed and providing the light blocking layer comprising the light blocking material layer remaining on the first buffer layer having the fourth thickness, and
wherein side surfaces of the light blocking layer contact the first buffer layer.
